(19) United States
(12) Patent Application Publication
(10) Pub. No.: US 2025/0166722 A1
(43) Pub. Date: May 22, 2025

(54) APPARATUS AND METHODS FOR MANAGING WEAR LEVELING IN MEMORY

(71) Applicant: MICRON TECHNOLOGY, INC., BOISE, ID (US)

(72) Inventor: Mohammed A. Khan, Fremont, CA (US)

(73) Assignee: MICRON TECHNOLOGY, INC., BOISE, ID (US)

(21) Appl. No.: 18/938,753

(22) Filed: Nov. 6, 2024

Related U.S. Application Data
(60) Provisional application No. 63/600,133, filed on Nov. 17, 2023.

(51) Int. Cl. G11C 29/56; G11C 16/34

(52) U.S. Cl. CPC G11C 29/56004; G11C 16/349; G11C 29/56016

(57) ABSTRACT

Systems might include tester hardware for connection to a die containing a memory comprising a plurality of groupings of memory cells and a predictive model in communication with the tester hardware, wherein a controller of the tester hardware is configured to generate characterization data corresponding to a first grouping of memory cells, wherein the predictive model is configured to generate an indication of expected endurance for the first grouping of memory cells in response to the characterization data in response to process data corresponding to the first grouping of memory cells, and wherein the controller is further configured to store a value to the memory indicative of the indication of expected endurance. Methods could use the predictive model in wear leveling within a memory, and memories could use information regarding expected endurance in wear leveling.

This application claims the benefit of U.S. Provisional Application No. 63/600,133, filed on Nov. 17, 2024, hereby incorporated herein in its entirety by reference.

### TECHNICAL FIELD

The present disclosure relates generally to memory and, in particular, in one or more embodiments, the present disclosure relates to apparatus and methods for managing wear leveling in memory.

### BACKGROUND

Memories (e.g., memory devices) are typically provided as internal, semiconductor, integrated circuit devices in computers or other electronic devices. There are many different types of memory including random-access memory (RAM), read only memory (ROM), dynamic random access memory (DRAM), synchronous dynamic random access memory (SDRAM), and flash memory.

Flash memory has developed into a popular source of non-volatile memory for a wide range of electronic applications. Flash memory typically use a one-transistor memory cell that allows for high memory densities, high reliability, and low power consumption. Changes in threshold voltage (Vt) of the memory cells, through programming (which is often referred to as writing) of charge storage structures (e.g., floating gates or charge traps) or other physical phenomena (e.g., phase change or polarization), determine the data state (e.g., data value) of each memory cell. Common uses for flash memory and other non-volatile memory include personal computers, personal digital assistants (PDAs), digital cameras, digital media players, digital recorders, games, appliances, vehicles, wireless devices, mobile telephones, and removable memory modules, and the uses for non-volatile memory continue to expand.

A NAND flash memory is a common type of flash memory device, so called for the logical form in which the basic memory cell configuration is arranged. Typically, the array of memory cells for NAND flash memory is arranged such that the control gate of each memory cell of a row of the array is connected together to form an access line, such as a word line. Columns of the array include strings (often termed NAND strings) of memory cells connected together in series between a pair of select gates, e.g., a source select transistor and a drain select transistor. Each source select transistor might be connected to a source, while each drain select transistor might be connected to a data line, such as column bit line. Variations using more than one select gate between a string of memory cells and the source, and/or between the string of memory cells and the data line, are known.

In programming memory, memory cells might be programmed as what are often termed single-level cells (SLC). SLC might use a single memory cell to represent one digit (e.g., one bit) of data. For example, in SLC, a Vt of 2.5V or higher might indicate a programmed memory cell (e.g., representing a logical 0) while a Vt of −0.5V or lower might indicate an erased memory cell (e.g., representing a logical 1). Such memory might achieve higher levels of storage capacity by including multi-level cells (MLC), triple-level cells (TLC), quad-level cells (QLC), etc., or combinations thereof in which the memory cell has multiple levels that enable more digits of data to be stored in each memory cell. For example, MLC might be configured to store two digits of data per memory cell represented by four Vt ranges, TLC might be configured to store three digits of data per memory cell represented by eight Vt ranges, QLC might be configured to store four digits of data per memory cell represented by sixteen Vt ranges, and so on.

Each time new data is to be programmed to a memory cell, that memory cell might first be placed in an erased state. As such, memory cells might each be expected to experience a number of program/erase cycles during use. These program/erase cycles can cause wear of the memory cells to occur. As the memory cells wear, an increased probability of failures might occur.

Wear leveling is often utilized to address these wear issues. Generally, wear leveling refers to moving data and/or adjusting where data is stored in the memory device in an attempt to spread the wear effects around the device. Wear leveling is often performed autonomously by the memory as a background operation, e.g., an operation not visible to a normal user of the memory. Alternatively, wear leveling can be controlled by an external controller, e.g., a memory controller. Either way, wear leveling generally involves tracking the use of blocks of memory cells or other groupings of memory cells to permit memory cells experiencing lower levels of use to be selected more often than memory cells experiencing higher levels of use.

### BRIEF DESCRIPTION OF THE DRAWINGS

FIG. 1 is a simplified block diagram of a memory in communication with a processor as part of an electronic system, according to an embodiment.

FIGS. 2A-2C are schematics of portions of an array of memory cells that could be used in a memory of the type described with reference to FIG. 1.

FIG. 3 illustrates an example computing system that includes an AI (artificial intelligence) accelerator in accordance with an embodiment.

FIG. 4 depicts a flow diagram of an example process in accordance with an embodiment.

FIG. 5 depicts a block schematic of a tester hardware that might be used for performing testing of dies of a wafer in accordance with an embodiment.

FIG. 6 depicts a wafer having a number of dies for use in describing location information for dies in accordance with various embodiments.

FIG. 7 depicts a block schematic of a processing chamber containing a wafer for performing a processing step in the fabrication of the dies in accordance with various embodiments.

FIG. 8 depicts a plot of a number of failed digits as a function of a number of program/erase cycles for a number of performance zones that could be used with various embodiments.

FIGS. 9A-9D depict representations of entries of various datasets for use with various embodiments.

FIG. 10 depicts a flow diagram of an example process in accordance with an embodiment.

FIGS. 11A-11C depict representations of entries of various datasets for memories under test for use with various embodiments.

FIG. 12 depicts a look-up table containing entries corresponding to groupings of memory cells of a memory in accordance with an embodiment.

FIGS. 13A-13C depict various examples of how counts might be stored in relation to blocks of memory cells in accordance with some embodiments.

FIG. 14 depicts a flowchart of a method of operating a system containing a tester hardware and a predictive model according to an embodiment.

FIG. 15 depicts a flowchart of a method for performing wear leveling according to an embodiment.

FIG. 16 depicts a flowchart of a method of operating a memory according to an embodiment.

FIGS. 17A-17B depict stages of traditional wear leveling in a memory.

FIGS. 18A-18D depict stages of wear leveling in a memory in accordance with embodiments.

### DETAILED DESCRIPTION

In the following detailed description, reference is made to the accompanying drawings that form a part hereof, and in which is shown, by way of illustration, specific embodiments. In the drawings, like reference numerals describe substantially similar components throughout the several views. Other embodiments might be utilized and structural, logical and electrical changes might be made without departing from the scope of the present disclosure. The following detailed description is, therefore, not to be taken in a limiting sense.

The term “wafer” as used herein can refer to, for example, any material upon which, and/or in which, structures including integrated circuitry, whether active or passive, might be partially or completely fabricated, and includes conventional semiconductor (e.g., silicon) wafers, as well as bulk substrates of semiconductor and other materials.

It is recognized herein that even where values might be intended to be equal, variabilities and accuracies of industrial processing and operation might lead to differences from their intended values. These variabilities and accuracies will generally be dependent upon the technology utilized in fabrication and operation of the integrated circuit device. As such, if values are intended to be equal, those values are deemed to be equal regardless of their resulting values.

Integrated circuit fabrication is generally a complex process that might involve several hundred processing steps spread over a period of weeks or even months. Although multiple dies might be fabricated on a same wafer, performance characteristics from die-to-die might be expected to vary due to the inherent variability of industrial processing. Similarly, different blocks of memory cells within a single die might also be expected to vary in their performance characteristics from block-to-block. The same generally holds true for different memory planes, e.g., collections of blocks of memory cells, as well as different sub-divisions of a block of memory cells, e.g., pages or sub-blocks of memory cells. While physical characteristics of circuit elements can be altered within a die, or among different dies of a wafer, in order to mitigate some of the known locational variations to be expected, these solutions are becoming less effective as the number of layers forming an individual die increases, and the number of dies per wafer increases.

Wear leveling typically seeks to control usage of groupings of memory cells within an array of memory cells to facilitate similar usage of each grouping of memory cells. Typically, a grouping of memory cells for wear leveling might be a block of memory cells. However, groupings of memory cells that are the subject of wear leveling might be pages of memory cells (e.g., physical pages of memory cells of a block of memory cells), sub-blocks of memory cells (e.g., subsets of pages of memory cells of a block of memory cells), a block of memory cells, super blocks of memory cells (e.g., two or more blocks of memory cells sharing the same set of access lines), or any other set of memory cells that might be programmed and erased as a unit.

To facilitate similar usage, wear leveling schemes typically increase the probability that a grouping of memory cells having a lesser number of program/erase cycles will be selected for a programming operation than a grouping of memory cells having a greater number of program/erase cycles. The programming operation might be performed in response to data received from an external device associated with a write command, or it might be performed in response to movement of data within the memory as part of a housekeeping operation. Increasing the probability of using lower cycled memory cells can be as simple as selecting a free (e.g., not containing valid or obsolete data) grouping of memory cells that has a lowest number of program/erase cycles for each programming operation. However, other considerations can be taken into account. Various embodiments can be used with any wear leveling scheme that makes its decision in response to at least a count value indicative of a level of wear experienced by a grouping of memory cells.

A problem with typical wear leveling schemes is that different groupings of memory cells generally reach a failure point at differing amounts of wear, e.g., due to the process variability discussed above. A failure point might be defined as having a number of failed bits that exceeds some limit that is less than or equal to a number of failed bits that an error correction scheme of the memory is capable of correcting.

Because typical wear leveling schemes presume that all groupings of memory cells have a similar level of endurance, groupings of memory cells having a lower endurance might be over-utilized, while groupings of memory cells having a higher endurance might be under-utilized. As a result, groupings of memory cells having lower endurance might fail long before groupings of memory cells having higher endurance, which can reduce the rated capacity of a memory long before its end-of-life. Various embodiments might seek to facilitate usage rates of groupings of memory cells such that an end-of-life of individual groupings of memory cells might occur closer to an end-of-life of the memory containing the groupings of memory cells, such that the memory might maintain its rated capacity longer.

Various embodiments include a system that might generate a predictive model for predicting an expected endurance of a grouping of memory cells based on characterization data and process data via machine learning techniques. In some embodiments, the system might train a predictive model based on characterization data for various groupings of memory cells of a die of a wafer, including data from performance testing of individual dies and information regarding the location of the groupings of memory cells within the dies and within the wafer, and process data generated during fabrication of the dies on the wafer.

In operation, the system may train a predictive model with characterization data labeled (e.g., categorized) for demonstrated endurance (e.g., a measured useful number of program/erase cycles or other indicator of wear) of individual groupings of memory cells, and the process data associated with those groupings of memory cells. For example, the system might determine relationships between the demonstrated endurance and at least some of the characterization and process data. Upon training (e.g., generating) a predictive model, various embodiments might be used to predict (e.g., estimate) an endurance (e.g., expected endurance) of an individual grouping of memory cells based on its associated process data, information regarding its location within its corresponding die and wafer, and little to no data from performance testing (e.g., relative to the training dataset). In response to the predicted endurance of the various groupings of memory cells of a memory (e.g., the die), data could be stored to the memory to reduce the likelihood that groupings of memory cells having a low predicted endurance would be selected for a programming operation versus groupings of memory cells having a higher predicted endurance, and to increase the likelihood that groupings of memory cells having a high predicted endurance would be selected for a programming operation versus groupings of memory cells having a lower predicted endurance. As a result, various embodiments might facilitate an improved duration of a rated capacity of a memory.

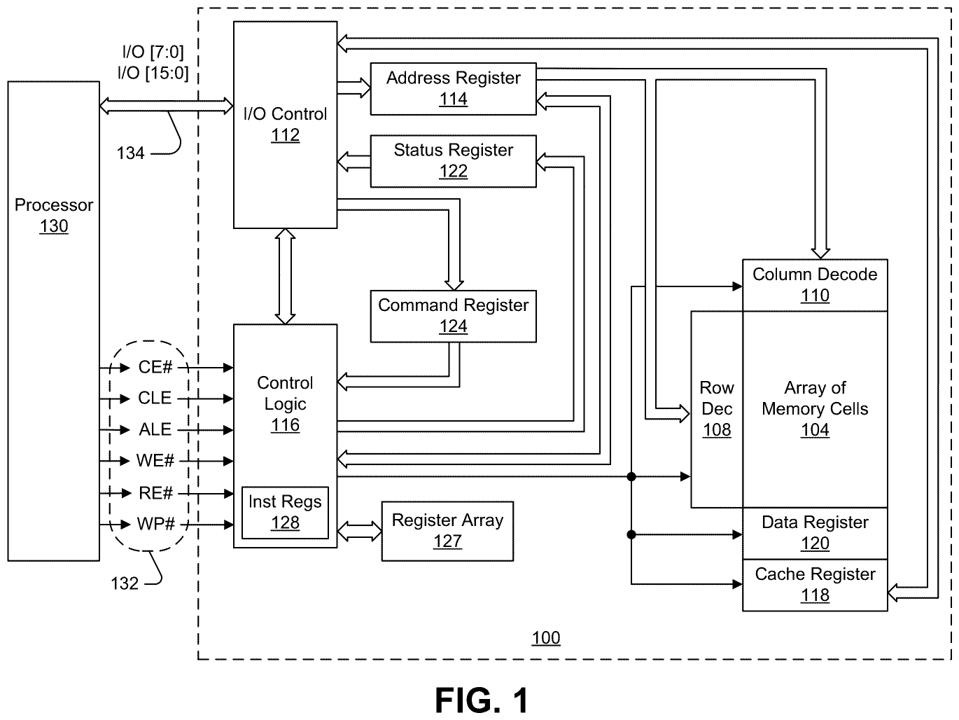

FIG. 1 is a simplified block diagram of a first apparatus, in the form of a memory (e.g., memory device) 100, in communication with a second apparatus, in the form of a processor 130, as part of a third apparatus, in the form of an electronic system, according to an embodiment. Some examples of electronic systems include personal computers, personal digital assistants (PDAs), digital cameras, digital media players, digital recorders, games, appliances, vehicles, wireless devices, mobile telephones and the like. The processor 130, e.g., a controller external to the memory device 100, might be a memory controller or other external host device.

Memory device 100 includes an array of memory cells 104 that might be logically arranged in rows and columns. Memory cells of a logical row are typically connected to the same access line (commonly referred to as a word line) while memory cells of a logical column are typically selectively connected to the same data line (commonly referred to as a bit line). A single access line might be associated with more than one logical row of memory cells and a single data line might be associated with more than one logical column. Memory cells (not shown in FIG. 1) of at least a portion of array of memory cells 104 are capable of being programmed to one of at least two target data states.

Row decode circuitry 108 and column decode circuitry 110 are provided to decode address signals. Address signals are received and decoded to access the array of memory cells 104. Memory device 100 also includes input/output (I/O) control circuitry 112 to manage input of commands, addresses and data to the memory device 100 as well as output of data and status information from the memory device 100. An address register 114 is in communication with I/O control circuitry 112, and with row decode circuitry 108 and column decode circuitry 110, to latch the address signals prior to decoding. A command register 124 is in communication with I/O control circuitry 112 and control logic 116 to latch incoming commands.

A controller (e.g., the control logic 116 internal to the memory device 100) controls access to the array of memory cells 104 in response to the commands and might generate status information for the external processor 130, i.e., control logic 116 is configured to perform array operations (e.g., sensing operations [which might include read operations and verify phases of programming operations], programming operations [e.g., write operations], and/or erase operations) on the array of memory cells 104. The control logic 116 is in communication with row decode circuitry 108 and column decode circuitry 110 to control the row decode circuitry 108 and column decode circuitry 110 in response to the addresses. The control logic 116 might include instruction registers 128 which might represent computer-usable memory for storing computer-readable instructions. For some embodiments, the instruction registers 128 might represent firmware. Alternatively, the instruction registers 128 might represent a grouping of memory cells, e.g., reserved block(s) of memory cells, of the array of memory cells 104. The control logic 116 might be configured to cause the memory, e.g., to cause relevant components of the memory, to perform methods according to various embodiments, e.g., through execution of computer-readable instructions stored to the instruction registers 128.

Control logic 116 might also be in communication with a cache register 118. Cache register 118 latches data, either incoming or outgoing, as directed by control logic 116 to temporarily store data while the array of memory cells 104 is busy writing or reading, respectively, other data. During a programming operation, data might be passed from the cache register 118 to the data register 120 for transfer to the array of memory cells 104, then new data might be latched in the cache register 118 from the I/O control circuitry 112. During a read operation, data might be passed from the cache register 118 to the I/O control circuitry 112 for output to the external processor 130, then new data might be passed from the data register 120 to the cache register 118. The cache register 118 and/or the data register 120 might form (e.g., might form a portion of) a page buffer of the memory device 100. A data register 120 might further include page buffer circuits (not shown in FIG. 1) to sense a data state of a memory cell of the array of memory cells 104, e.g., by sensing a state of a data line connected to that memory cell. A status register 122 might be in communication with I/O control circuitry 112 and control logic 116 to latch the status information for output to the processor 130.

A register array 127 might be in communication with the control logic 116. The register array 127 might represent volatile memory, non-volatile memory, latches, fuses/anti-fuses, or other storage location, e.g., volatile or non-volatile. For some embodiments, the register array 127 might include a portion of the array of memory cells 104. The register array 127 might store trims. Trims might be used by the memory to set values used by an array operation, e.g., voltage levels, timing characteristics, etc., or might be used to selectively activate or deactivate features of the memory. The register array 127 might further include read-only memory that might be fabricated to contain data identifying a location of the memory 100 relative to a semiconductor wafer upon which it was fabricated.

Memory device 100 receives control signals at control logic 116 from processor 130 over a control link 132. The control signals might include a chip enable CE #, a command latch enable CLE, an address latch enable ALE, a write enable WE #, a read enable RE #, and a write protect WP #. Additional or alternative control signals (not shown) might be further received over control link 132 depending upon the nature of the memory device 100. Memory device 100 receives command signals (which represent commands), address signals (which represent addresses), and data signals (which represent data) from processor 130 over a multiplexed input/output (I/O) bus 134 and outputs data to processor 130 over I/O bus 134.

For example, the commands might be received over input/output (I/O) pins [7:0] of I/O bus 134 at I/O control circuitry 112 and might then be written into command register 124. The addresses might be received over input/output (I/O) pins [7:0] of I/O bus 134 at I/O control circuitry 112 and might then be written into address register 114. The data might be received over input/output (I/O) pins [7:0] for an 8-bit device or input/output (I/O) pins [15:0] for a 16-bit device at I/O control circuitry 112 and then might be written into cache register 118. The data might be subsequently written into data register 120 for programming the array of memory cells 104. Data might also be output over input/output (I/O) pins [7:0] for an 8-bit device or input/output (I/O) pins [15:0] for a 16-bit device. Although reference might be made to I/O pins, they might include any conductive nodes providing for electrical connection to the memory device 100 by an external device (e.g., processor 130), such as conductive pads or conductive bumps as are commonly used.

It will be appreciated by those skilled in the art that additional circuitry and signals can be provided, and that the memory device 100 of FIG. 1 has been simplified. It should be recognized that the functionality of the various block components described with reference to FIG. 1 might not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

Additionally, while specific I/O pins are described in accordance with popular conventions for receipt and output of the various signals, it is noted that other combinations or numbers of I/O pins (or other I/O node structures) might be used in the various embodiments.

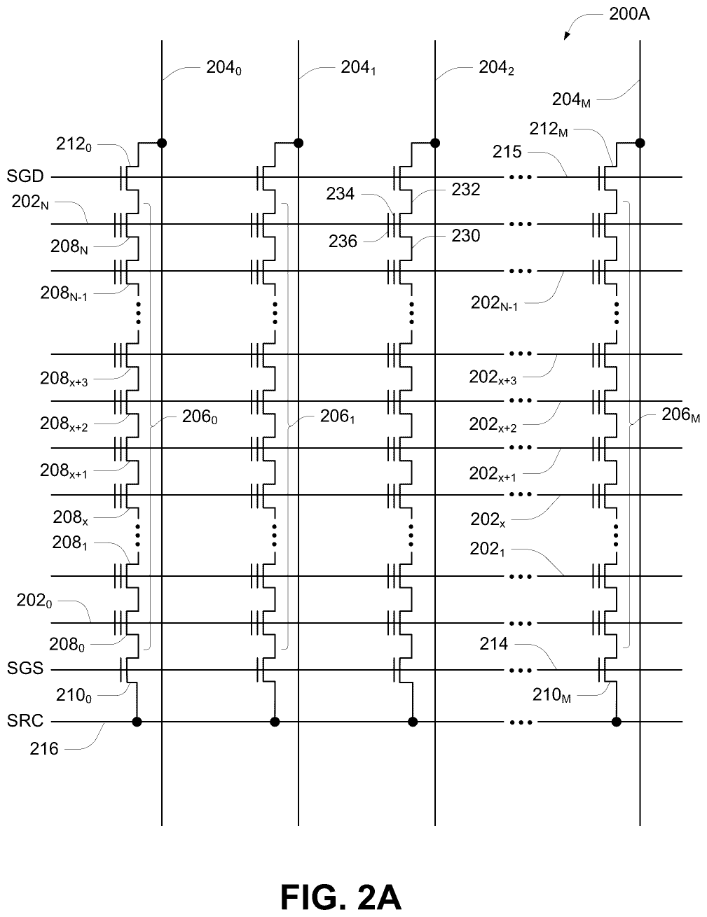

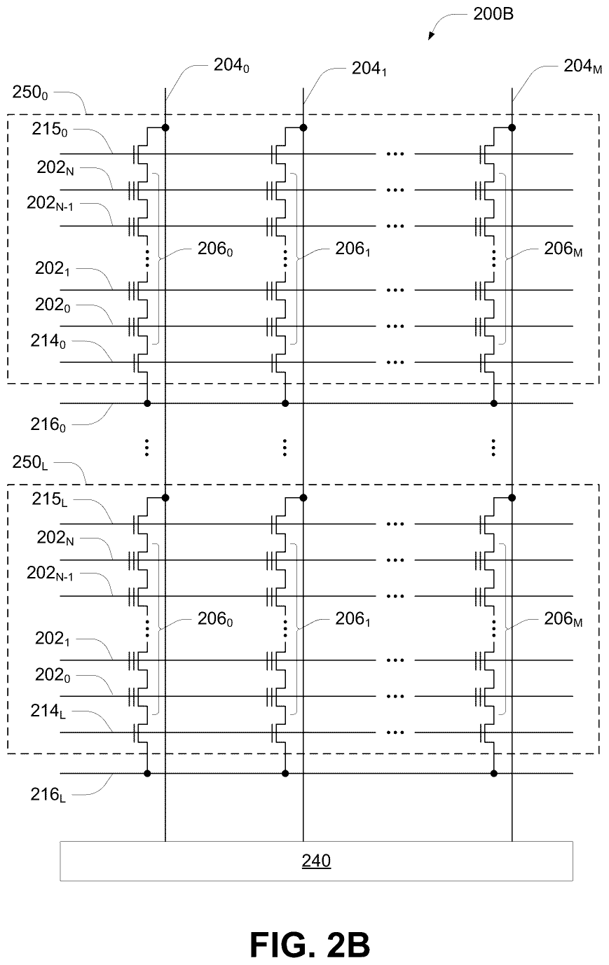

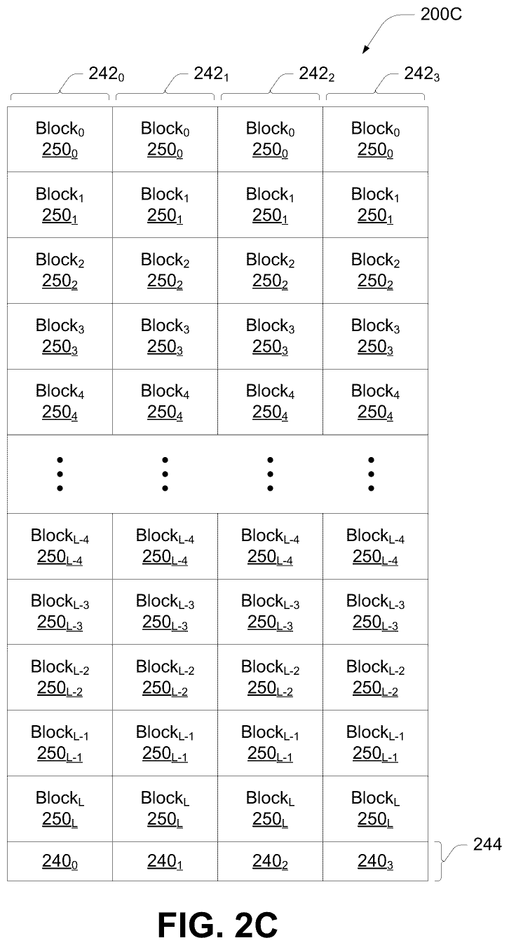

FIG. 2A is a schematic of a portion of an array of memory cells 200A, such as a NAND memory array, as could be used in a memory of the type described with reference to FIG. 1, e.g., as a portion of array of memory cells 104. Memory array 200A includes access lines (e.g., word lines) 202₀ to 202_{N}, and data lines (e.g., bit lines) 204₀ to 204_{M}. The access lines 202 might be connected to global access lines (e.g., global word lines), not shown in FIG. 2A, in a many-to-one relationship. For some embodiments, memory array 200A might be formed over a semiconductor that, for example, might be conductively doped to have a conductivity type, such as a p-type conductivity, e.g., to form a p-well, or an n-type conductivity, e.g., to form an n-well.

Memory array 200A might be arranged in rows (each corresponding to an access line 202) and columns (each corresponding to a data line 204). Each column might include a string of series-connected memory cells (e.g., non-volatile memory cells), such as one of NAND strings 206₀ to 206_{M}. Each NAND string 206 might be connected (e.g., selectively connected) to a common source (SRC) 216 and might include memory cells 208₀ to 208_{N}. The memory cells 208 might represent non-volatile memory cells for storage of data. The memory cells 208₀ to 208_{N} might include memory cells intended for storage of data, and might further include other memory cells not intended for storage of data, e.g., dummy memory cells. Dummy memory cells are typically not accessible to a user of the memory, and are instead typically incorporated into the string of series-connected memory cells for operational advantages that are well understood.

The memory cells 208 of each NAND string 206 might be connected in series between a select gate 210 (e.g., a field-effect transistor), such as one of the select gates 210₀ to 210_{M} (e.g., that might be source select transistors, commonly referred to as select gate source), and a select gate 212 (e.g., a field-effect transistor), such as one of the select gates 212₀ to 212_{M} (e.g., that might be drain select transistors, commonly referred to as select gate drain). Select gates 210₀ to 210_{M} might be commonly connected to a select line 214, such as a source select line (SGS), and select gates 212₀ to 212_{M} might be commonly connected to a select line 215, such as a drain select line (SGD). Although depicted as traditional field-effect transistors, the select gates 210 and 212 might utilize a structure similar to (e.g., the same as) the memory cells 208. The select gates 210 and 212 might represent a plurality of select gates connected in series, with each select gate in series configured to receive a same or independent control signal. In addition, for embodiments utilizing a plurality of select gates connected in series, such select gates might be configured to have the same or different threshold voltages. For example, where gate-induced drain leakage current (GIDL) is desired for programming operations, one or more select gates of the series-connected select gates might have a different (e.g., lower) threshold voltage than one or more other select gates of the series-connected select gates.

A source of each select gate 210 might be connected to common source 216. The drain of each select gate 210 might be connected to a memory cell 208₀ of the corresponding NAND string 206. For example, the drain of select gate 210₀ might be connected to memory cell 208₀ of the corresponding NAND string 206₀. Therefore, each select gate 210 might be configured to selectively connect a corresponding NAND string 206 to common source 216. A control gate of each select gate 210 might be connected to select line 214.

The drain of each select gate 212 might be connected to the data line 204 for the corresponding NAND string 206. For example, the drain of select gate 212₀ might be connected to the data line 204₀ for the corresponding NAND string 206₀. The source of each select gate 212 might be connected to a memory cell 208_{N} of the corresponding NAND string 206. For example, the source of select gate 212₀ might be connected to memory cell 208_{N} of the corresponding NAND string 206₀. Therefore, each select gate 212 might be configured to selectively connect a corresponding NAND string 206 to the corresponding data line 204. A control gate of each select gate 212 might be connected to select line 215.

The memory array in FIG. 2A might be a quasi-two-dimensional memory array and might have a generally planar structure, e.g., where the common source 216, NAND strings 206 and data lines 204 extend in substantially parallel planes. Alternatively, the memory array in FIG. 2A might be a three-dimensional memory array, e.g., where NAND strings 206 might extend substantially perpendicular to a plane containing the common source 216 and to a plane containing the data lines 204 that might be substantially parallel to the plane containing the common source 216.

Typical construction of memory cells 208 includes a data-storage structure 234 (e.g., a floating gate, charge trap, or other structure configured to store charge) that can determine a data state of the memory cell (e.g., through changes in threshold voltage), and a control gate 236, as shown in FIG. 2A. The data-storage structure 234 might include both conductive and dielectric structures while the control gate 236 is generally formed of one or more conductive materials. In some cases, memory cells 208 might further have a defined source/drain (e.g., source) 230 and a defined source/drain (e.g., drain) 232. Memory cells 208 have their control gates 236 connected to (and in some cases form) an access line 202.

A column of the memory cells 208 might be a NAND string 206 or a plurality of NAND strings 206 selectively connected to a given data line 204. A row of the memory cells 208 might be memory cells 208 commonly connected to a given access line 202. A row of memory cells 208 can, but need not, include all memory cells 208 commonly connected to a given access line 202. Rows of memory cells 208 might often be divided into one or more groups of physical pages of memory cells 208, and physical pages of memory cells 208 often include every other memory cell 208 commonly connected to a given access line 202. For example, memory cells 208 commonly connected to access line 202_{N} and selectively connected to even data lines 204 (e.g., data lines 204₀, 204₂, 204₄, etc.) might be one physical page of memory cells 208 (e.g., even memory cells) while memory cells 208 commonly connected to access line 202_{N} and selectively connected to odd data lines 204 (e.g., data lines 204₁, 204₃, 204₅, etc.) might be another physical page of memory cells 208 (e.g., odd memory cells). Although data lines 204₃-204₅ are not explicitly depicted in FIG. 2A, it is apparent from the figure that the data lines 204 of the array of memory cells 200A might be numbered consecutively from data line 204₀ to data line 204_{M}. Other groupings of memory cells 208 commonly connected to a given access line 202 might also define a physical page of memory cells 208. For certain memory devices, all memory cells commonly connected to a given access line might be deemed a physical page of memory cells. The portion of a physical page of memory cells (which, in some embodiments, could still be the entire row) that is read during a single read operation or programmed during a single programming operation (e.g., an upper or lower page of memory cells) might be deemed a logical page of memory cells. A block of memory cells might include those memory cells that are configured to be erased together, such as all memory cells connected to access lines 202₀-202_{N} (e.g., all NAND strings 206 sharing common access lines 202). Unless expressly distinguished, a reference to a page of memory cells herein refers to the memory cells of a logical page of memory cells.

Although the example of FIG. 2A is discussed in conjunction with NAND flash, the embodiments and concepts described herein are not limited to a particular array architecture or structure, and can include other structures (e.g., SONOS or other data storage structure configured to store charge) and other architectures (e.g., AND arrays, NOR arrays, etc.).

A three-dimensional NAND memory array might incorporate vertical structures which might include semiconductor pillars, which might be solid or hollow, where a portion of a pillar might act as a channel region of the memory cells of NAND strings 206, e.g., a region through which current might flow when a memory cell, e.g., a field-effect transistor, is activated. Multiple NAND strings 206 might be selectively connected to the same data line 204. Subsets of NAND strings 206 might be connected to their respective data lines 204 by biasing respective select lines 215 to selectively activate particular select transistors 212 each between a NAND string 206 and a data line 204. The select transistors 210 for each NAND string 206 might be activated by biasing the select line 214. Each access line 202 might be connected to multiple rows of memory cells of a three-dimensional NAND memory array. Rows of memory cells that are commonly connected to each other by a particular access line 202 might collectively be referred to as tiers.

FIG. 2B is a further schematic of a portion of an array of memory cells 200B as could be used in a memory of the type described with reference to FIG. 1, e.g., as a portion of array of memory cells 104. Like numbered elements in FIG. 2B correspond to the description as provided with respect to FIG. 2A. Array of memory cells 200B might include strings of series-connected memory cells (e.g., NAND strings) 206, access (e.g., word) lines 202, data (e.g., bit) lines 204, select lines 214 (e.g., source select lines), select lines 215 (e.g., drain select lines) and source 216 as depicted in FIG. 2A. A portion of the array of memory cells 200A might be a portion of the array of memory cells 200B, for example. FIG. 2B depicts groupings of NAND strings 206 into blocks of memory cells 250, e.g., blocks of memory cells 250₀-250_{L}. Blocks of memory cells 250 might be groupings of memory cells 208 that might be erased together in a single erase operation, sometimes referred to as erase blocks. Each block of memory cells 250 might represent those NAND strings 206 commonly associated with a single select line 215, e.g., select line 2150. The source 216 for the block of memory cells 250₀ might be a same source as the source 216 for the block of memory cells 250_{L}. For example, each block of memory cells 250₀-250_{L}, might be commonly selectively connected to the source 216. Access lines 202 and select lines 214 and 215 of one block of memory cells 250 might have no direct connection to access lines 202 and select lines 214 and 215, respectively, of any other block of memory cells of the blocks of memory cells 250₀-250_{L}.

The data lines 204₀-204_{M} might be connected (e.g., selectively connected) to a buffer portion 240, which might be a portion of a page buffer of the memory. The buffer portion 240 might correspond to a memory plane (e.g., the set of blocks of memory cells 250₀-250_{L}). The buffer portion 240 might include sense circuits (not shown in FIG. 2B) for sensing data values indicated on respective data lines 204.

FIG. 2C is a block schematic of a portion of an array of memory cells that could be used in a memory of the type described with reference to FIG. 1. The array of memory cells 200C is depicted to have four memory planes 242 (e.g., memory planes 242₀-242₃), each in communication with a respective buffer portion 240 (e.g., buffer portions 240₀-240₃), which might collectively form a data buffer (e.g., page buffer) 244. While four memory planes 242 are depicted, other numbers of memory planes 242 might be commonly in communication with a data buffer 244. Each memory plane 242 is depicted to include L+1 blocks of memory cells 250 (e.g., blocks of memory cells 250₀-250_{L}).

FIG. 2C might also be used to depict the concept of a super block of memory cells, e.g., two or more blocks of memory cells 250 sharing the same set of access lines. For example, a first super block of memory cells might include blocks of memory cells 250₀ of memory planes 242₀ and 242₁, and a second super block of memory cells might include blocks of memory cells 250₀ of memory planes 242₂ and 242₃. Alternatively, a super block of memory cells might include blocks of memory cells 250₀ of memory planes 242₀-242₃.

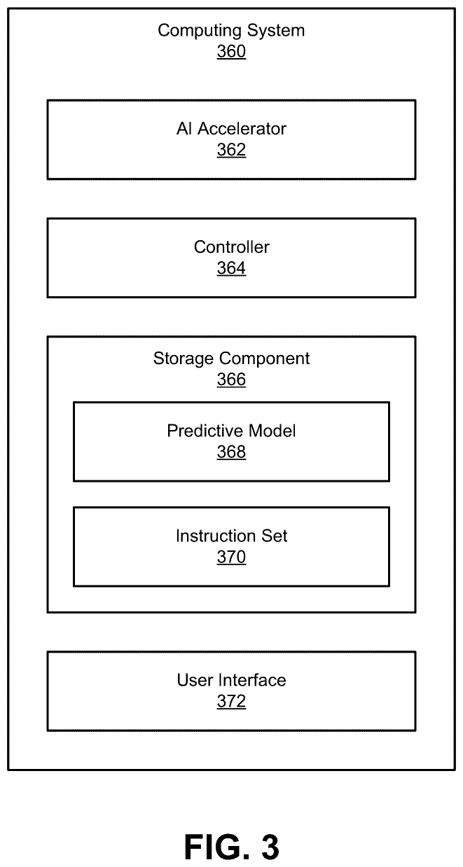

FIG. 3 illustrates an example computing system 360 that includes an AI (artificial intelligence) accelerator 362 in accordance with some embodiments. The AI accelerator 362 can include hardware, software, and/or firmware that is configured to enable the computing system 360 to perform operations (e.g., logic operations, among other operations) associated with AI operations using one or more AI models. In some embodiments, the AI accelerator 362 can include special purpose circuitry in the form of an ASIC (application specific integrated circuit), FPGA (field programmable gate arrays), state machine, and/or other logic circuitry that can allow the AI accelerator 362 to orchestrate and/or perform operations described herein. Alternatively, the AI accelerator 362 might be a function of the controller 364 performing instructions from an instruction set 370 stored to the storage component 366. In some embodiments, AI operations can include machine learning or neural network operations, which can include training operations and/or inference operations.

Data stored in storage component 366 of the computing system 360 and/or external to the computing system 360 can be used in performing the AI operations. In some embodiments, the storage component 366 can also store a predictive model 368 and/or the instruction set 370. The storage component 366 can include volatile storage media (e.g., dynamic RAM, static RAM, data latches, etc.) and/or non-volatile storage media (e.g., flash memory, read only memory, disk drives, tape drives, solid state drives, etc.).

The predictive model 368 might represent instructions for use by the AI accelerator 362 and controller 364 configured to cause the computing system 360 to generate an indication of expected endurance for a grouping of memory cells in response to characterization data and process data for that grouping of memory cells. The predictive model 368 can be trained on the computing system 360 and/or remotely. For example, the predictive model 368 can be trained remotely in a cloud and transmitted to the computing system 360. Labeled characterization data and process data can be used to train the predictive model 368.

The computing system 360 can include a user interface 372. The user interface 372 can be generated by the computing system 360, e.g., by the controller 360 in response to instructions from the instruction set 370. The user interface 372 can be a graphical user interface (GUI) that can provide and receive information to and/or from the user of the computing system 360. In some approaches, the user interface 372 can be shown on a display of the computing system 360.

The AI accelerator 362 of the computing system 360 can receive data from one or more sources, e.g., tester hardware, external storage device, cloud storage, etc. Received data might include characterization data (e.g., labeled and unlabeled) including performance testing data for groupings of memory cells and location information corresponding to the groupings of memory cells, and associated process data (e.g., process data corresponding to a die or wafer being tested). The AI accelerator 362 can perform an AI operation on all or a portion of the received data.

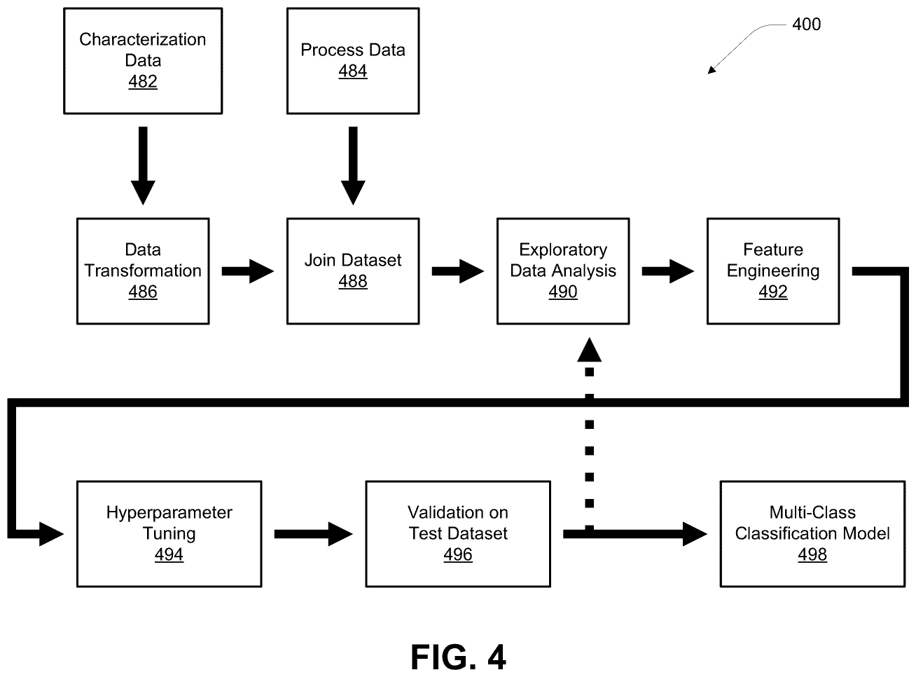

FIG. 4 depicts a flow diagram of an example process 400 in accordance with an embodiment. The process 400 might describe a process of training and tuning a predictive model (e.g., a machine learning model) to generate an indication of expected endurance of a grouping of memory cells.

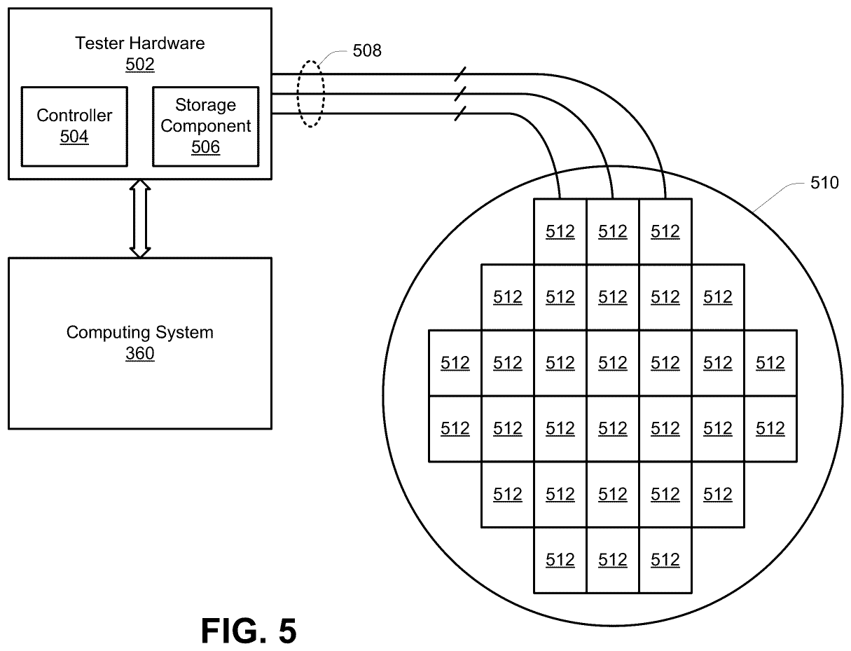

At 482, a set of characterization data might be received. The characterization data might include data from performance testing of various groupings of memory cells of individual dies of a wafer. FIG. 5 depicts a block schematic of tester hardware 502 that might be used for performing testing of the dies 512 of a wafer 510 in accordance with an embodiment. The tester hardware 502 might include a controller 504. The controller 504 might be configured to cause the tester hardware 502 to perform testing on the groupings of memory cells (not depicted in FIG. 4) of the dies 512 of the wafer 510 in response to computer-readable instructions stored to the storage component 506. The storage component 506 can include volatile storage media (e.g., dynamic RAM, static RAM, data latches, etc.) and/or non-volatile storage media (e.g., flash memory, read only memory, disk drives, tape drives, solid state drives, etc.). Each die 512 might contain a memory 100 of FIG. 1. This relationship might be one-to-one, with each die 512 containing one memory 100. Accordingly, a grouping of memory cells could be identified as an element of a die 512 and an element of a memory 100. The tester hardware 502 might be in communication with a computing system 360. The communication between the tester hardware 502 and the computing system 360 might be direct, e.g., hardwire connection, or it might be remote, e.g., through a local network, the internet, or the cloud. Alternatively, the components of the tester hardware 502 and the computing system 360 might be contained within a single apparatus.

The tester hardware 502 might be in communication with one or more dies (e.g., memories) 512 and might be used to test multiple dies 512 in parallel or in sequence. The tester hardware 502 might be connected to the dies 512 using sets of leads 508 serving as address lines, DQ lines and control lines for the controller 504. Connecting the tester hardware 502 to the dies 512 might be accomplished using a set of leads 508 connected to the address lines, DQ lines and control lines on each die 512. The sets of leads 508 might be individually applied to each die 512 or they might be grouped to apply multiple sets of leads 508 substantially simultaneously. As shown in FIG. 5, testing might be performed prior to dicing the dies 512 from the wafer 510, such that each die 512 is an undiced semiconductor die. Alternatively, testing might be performed in a like manner subsequent to dicing and/or packaging of each die 512 by coupling the sets of leads 508 to the appropriate lines of each die 512 through the pins, bumps or other connectors of the diced or packaged memory device. Performance testing data collected by the tester hardware 502 might be stored to the storage component 506. Alternatively, or in addition, performance testing data generated by the tester hardware 502 might further be transmitted to the computing system 360 for use by the predictive model 368.

For example, dies 512 of a wafer 510 might be subjected to a number of operations (e.g., access operations, proprietary testing operations, etc.) that might generate data regarding timing of events (e.g., programming time, reading time, erasing time, etc.), numbers of iterations of an iterative operation (e.g., programming or erasing), number of failed digits in a sensing operation (e.g., reading or verifying), ramp and/or decay rates of voltages or currents, temperature of the die under test, etc. Such data might be generated more than once. For example, a number of failed digits in a sensing operation might be determined periodically over the course of thousands of program/erase cycles performed on the groupings of memory cells.

The performance testing of some of the groupings of memory cells might be continued until the groupings of memory cells and/or the dies 512 reach an end-of-life. For purposes herein, end-of-life might correspond to a point in time when groupings of memory cells and/or the die 512 are no longer deemed to be usable. For example, a threshold might be defined for a number of failed digits of a sensing operation of a grouping of memory cells, and end-of-life of that grouping of memory cells might correspond to when the threshold is first exceeded. Such a threshold might be determined in response to an error correction scheme used on the die 512, e.g., the threshold might be lower than or equal to a number of errors that are correctable by the error correction scheme. Alternatively or in addition, a threshold might be defined for a number of usable groupings of memory cells (e.g., not having reached end-of-life) available to a die 512, and end-of-life of that die 512 might correspond to when the number of usable groupings of memory cells first falls below that threshold.

For some embodiments, performance testing of some of the groupings of memory cells might be continued beyond the defined end-of-life of the groupings of memory cells and/or the dies 512, e.g., until a predetermined series of operations have been performed. This might include a predetermined number of program/erase cycles on each of the groupings of memory cells.

The characterization data might further include information regarding the location of the groupings of memory cells within the dies 512 (e.g., within the memories 100), and location of dies 512 within the wafer 510. Because variation is generally expected in the fabrication of integrated circuit devices, a die 512 from one location of a wafer 510 might be expected to exhibit different operating characteristics than dies 512 from other locations of the wafer. Similarly, a grouping of memory cells from one location of a die 512 might also be expected to exhibit different operating characteristics than groupings of memory cells from other locations of that die 512. As such, location information might be relevant to predicting expected endurance.

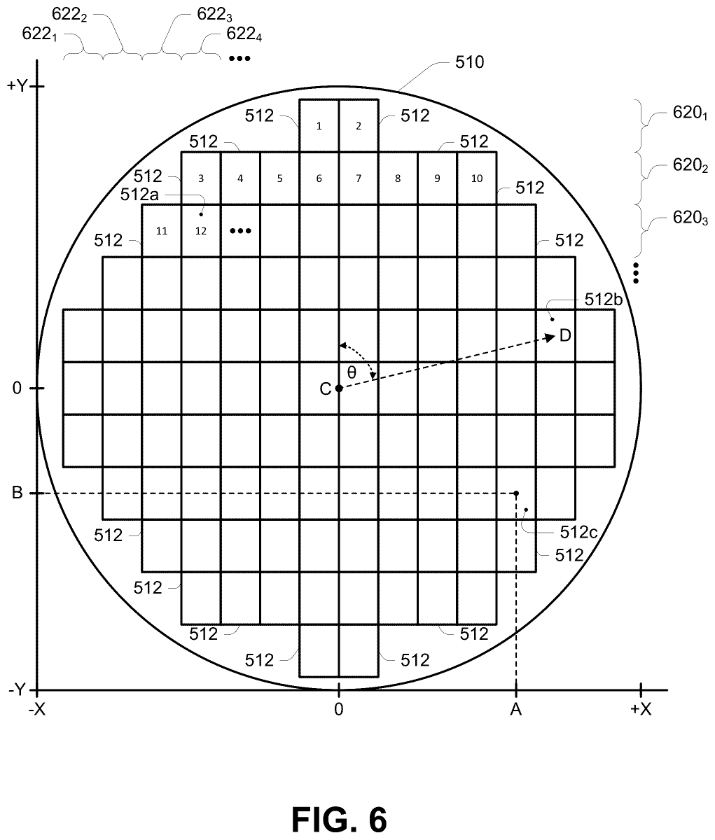

In identifying a location of a die 512 within a wafer 510, each die 512 might be identified by a die identification number, by row and column of the dies 512 on the wafer 510, by coordinates of a coordinate system, or by any other means of unique identification of a die 512. FIG. 6 depicts a wafer 510 having a number of dies 512 for use in describing location information for dies 512 in accordance with embodiments. The dies 512 could be uniquely identified by assigning a die identification number to each die 512, such as depicted with the dies 512 numbered 1 through 12 (for clarity, additional dies do not depict an identification number). Alternatively or in addition, the dies 512 could be identified by row 620 and column 622. For example, the die 512a might be identified by row 6203 and column 6224. Alternatively or in addition, the dies 512 could be identified by coordinates. For example, the die 512b might be identified in polar coordinates by a vector having a length D and an angle θ from a center C of the wafer 510. Alternatively or in addition, the die 512c might be identified by the coordinates (A, B), where A might have a value between −X and +X, where a width of the wafer 510 is less than or equal to 2X, and B might have a value between −Y and +Y, where a height of the wafer 510 is less than or equal to 2Y. Other manners of uniquely identifying each die 512 of a wafer 510 might also be used. Location information of a die 512 might be determined by a tester hardware 502, e.g., based on where its sets of leads 508 are applied to the wafer 510, or the location information of a die 512 (e.g., a die identification number) might be stored to the die 512 during fabrication by hard programming the location information, e.g., within the register array 127.

The groupings of memory cells within a die 512 might be further identified by an addressing scheme or otherwise. For example, groupings of memory cells could be identified by the common digits from each of the addresses used to identify each memory cell of the grouping of memory cells. In a simplistic example, consider the addresses 11100, 11101, 11110, and 11111 being used to identify the memory cells of a grouping of memory cells containing four memory cells. In this example, the address 111XX might be used to identify the grouping of memory cells, where X indicates a masked digit such that the address 111XX corresponds to a range of addresses of a memory. Alternatively, where a grouping of memory cells corresponds to a page of memory cells (e.g., logical or physical), that page of memory cells might be identified by a page number within a corresponding block of memory cells, its corresponding block of memory cells might be identified by a block number within a corresponding memory plane, and its corresponding memory plane might be identified by a plane number. Other means of identifying the location of a grouping of memory cells within a die 512 might also be used.

At 484, the process 400 might further include receiving a set of process data. The process data might include data collected before or during fabrication of the wafers corresponding to the dies of the characterization data received at 482. For example, integrated circuit fabrication is generally a complex process that might involve several hundred processing steps spread over a period of weeks or even months. These processing steps generally involve the formation, transformation, or patterning of individual layers making up the various active and/or passive circuit elements of an integrated circuit device, and include such things as physical vapor deposition, chemical vapor deposition, atomic layer deposition, spin-on deposition, photolithography, anisotropic removal, isotropic removal, chemical-mechanical polishing, oxidation, implantation, thermal annealing, plasma annealing, etc.

Various types of data might be collected during each of these processing steps from various sources. For example, flow sensors might measure flow rates, such as for reactants (e.g., precursors) and/or inert gas of a deposition process, temperature sensors might measure temperatures of one or more areas of the wafer surface and/or ambient temperature of the processing chamber, timers might measure duration of various events, imaging sensors might obtain image data of the wafer or defined areas of the wafer, pressure sensors might measure ambient pressure of the processing chamber and/or pressure being applied to the wafer surface such as by a polisher, energy sensors might measure energy of a plasma and/or an implantation, etc. In addition, lab testing data might be obtained for the raw materials involved, e.g., from the wafer to the materials used in forming, transforming, or patterning the layers during fabrication. Some data of the process data might be relevant to all dies of a wafer (e.g., ambient conditions of a processing chamber), while other data of the process data might be relevant to only a subset of dies of a wafer, or even a portions of a die (e.g., image data or surface temperature of a portion of a wafer).

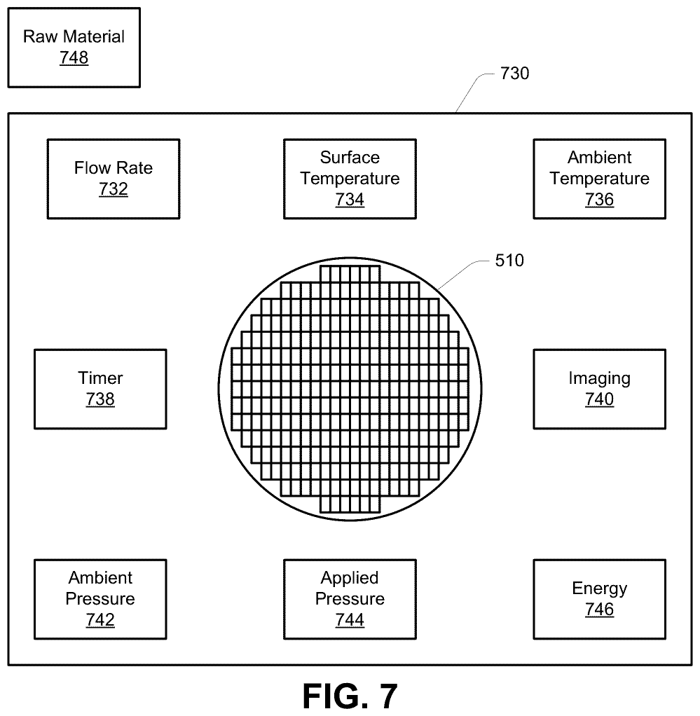

FIG. 7 depicts a block schematic of a processing chamber 730 containing a wafer 510 for performing a processing step in the fabrication of the dies 512 (not numbered in FIG. 7). The processing chamber 730 might represent any processing chamber used in the fabrication of the dies 512. The processing chamber 730 might contain one or more sensors for generating data corresponding to the dies 512 of the wafer 510. The processing chamber 730 might contain a flow rate sensor 732, a surface temperature sensor 734, an ambient temperature sensor 736, a timer 738, an imaging sensor 740, an ambient pressure sensor 742, an applied pressure sensor 744, and energy sensor 746, and/or one or more additional sensors for measuring other aspects of the wafer, the environment surrounding the wafer, and/or the processing being performed on the wafer. The raw material 748 might represent data provided by a supplier, or determined in-house or otherwise, regarding qualitative and/or quantitative analysis of the raw materials used in fabricating the dies 512. The process data generated or otherwise obtained during fabrication might be transmitted to a computing system 360. The communication between the devices obtaining process data and the computing system 360 might be direct, e.g., hardwire connection, or it might be remote, e.g., through a local network, the internet, or the cloud.

At 486, the characterization data might be transformed. Transformation of the characterization data might include converting the raw data to a format suitable for processing by the machine learning model. Transformation of the characterization data might further include generation of statistical data from the raw testing data, e.g., mean, median, mode, standard deviation, etc. Although not depicted, the process data might also be similarly transformed for format and/or statistical analysis. Transformation of the characterization data might further include grouping the characterization data by relative endurance. For example, the characterization data might be labeled such that the characterization data for each grouping of memory cells is associated with an indication of determined endurance in response to its corresponding performance testing. The indication of determined endurance might be assigned in response to one or more performance criteria, e.g., criteria defined by one or more data elements generated in response to the performance testing and/or one or more transformed data elements. As one example, data related to a number of failed digits of a sensing operation might be used to group characterization data by determined endurance.

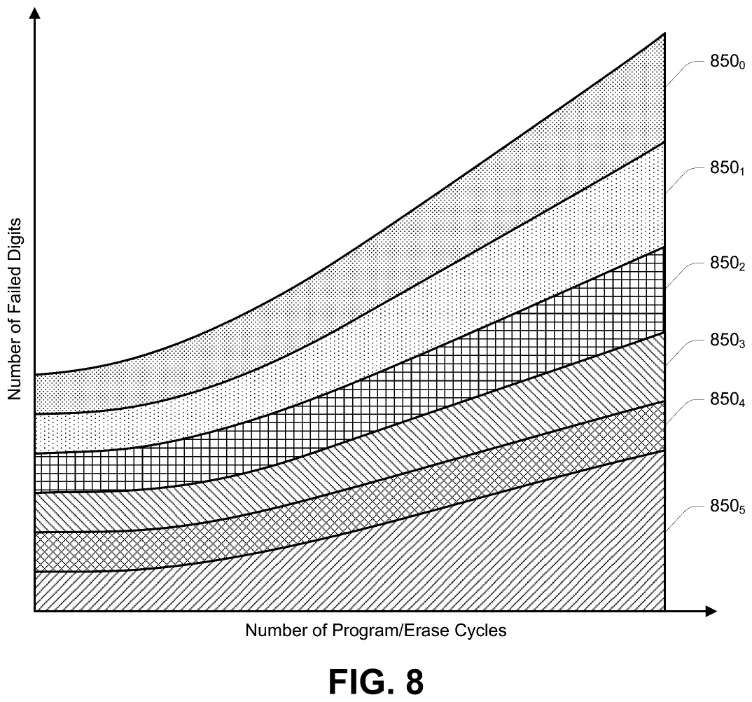

FIG. 8 depicts a plot of a number of failed digits as a function of a number of program/erase cycles for a number of performance zones 850 as could be used with various embodiments. The performance zone 850₅ might correspond to groupings of memory cells having a highest endurance, e.g., groupings of memory cells of a die 512 exhibiting a lowest number of failed digits for that die 512. The performance zone 850₀ might correspond to groupings of memory cells having a lowest endurance, e.g., groupings of memory cells of a die 512 exhibiting a highest number of failed digits for that die 512 without being deemed to be unusable. The intermediate performance zones 850₁-850₄ might correspond to groupings of memory cells having different endurance levels between the lowest endurance (e.g., performance zone 850₀) and the highest endurance (e.g., performance zone 850₅). Groupings of memory cells of a die 512 exhibiting a number of failed digits higher than the performance zone 850₀ might be deemed to be unusable.

As used herein, higher levels of endurance correspond to higher indications of determined endurance, and lower levels of endurance correspond to lower indications of determined endurance, regardless of a selected numbering or other ranking scheme associated with the indication of determined endurance. For example, considering a first indication of determined endurance and a second indication of determined endurance, the first indication of determined endurance is higher than the second indication of determined endurance if groupings of memory cells assigned the first indication of determined endurance have higher levels of endurance than groupings of memory cells assigned the second indication of determined endurance, and the first indication of determined endurance is lower than the second indication of determined endurance if groupings of memory cells assigned the first indication of determined endurance have lower levels of endurance than groupings of memory cells assigned the second indication of determined endurance.

While six performance zones 850 are depicted in FIG. 8, more or fewer performance zones 850 could be defined. In addition, the curves defining the interfaces between the performance zones 850 could be shaped differently. For performance zones using a number of failed digits as a function of a number of program/erase cycles, the curves might be expected to be increasing functions of the number of program/erase cycles. In addition, the slope of the curve defining an interface between a pair of adjacent performance zones 850 at any number of program/erase cycles, might further be equal to or less than the slope of the curve defining an interface between a higher pair of adjacent performance zones 850 at that number of program/erase cycles.

Note that FIG. 8 need not depict the actual performance characteristics of any individual grouping of memory cells. For example, a grouping of memory cells might initially exhibit a number of failed digits corresponding to one performance zone, e.g., performance zone 850₅, and might later exhibit a number of failed digits corresponding to the lower performance zone 850, e.g., performance zone 850₄. Alternatively, a grouping of memory cells might exhibit a more uniform behavior such that it might initially exhibit a number of failed digits corresponding to one performance zone 850, e.g., performance zone 850₄, and might later exhibit a number of failed digits corresponding to a higher performance zone 850, e.g., performance zone 850₅. For such embodiments, the characterization data corresponding to that grouping of memory cells might be assigned a determined endurance corresponding to the lowest performance zone 850 its performance testing indicates, might be assigned a determined endurance corresponding to the highest performance zone 850 its performance testing indicates, or might be assigned a determined endurance between the determined endurance corresponding to the lowest performance zone 850 its performance testing indicates and the determined endurance corresponding to the highest performance zone 850 its performance testing indicates.

Alternatively, the characterization data corresponding to a grouping of memory cells might be assigned a determined endurance in response to a number of program/erase cycles completed on that grouping of memory cells before its end-of-life is indicated. Table 1 depicts one possible relationship between the indications of determined endurance and the number of program/erase cycles completed on a grouping of memory cells before its end-of-life is indicated for various numbers (PE) of program/erase cycles, where PE0<PE1<PE2<PE3<PE4<PE5. PE0 might be equal to zero, but could have some positive value selected in response to a desired minimum level of endurance to be deemed usable. The range of PE values (e.g., PE5-PE0) might depend upon the memory density (e.g., number of digits of data to each memory cell) of the groupings of memory cells. For example, with SLC memory cells (e.g., one digit per memory cell), a useful life of over 100,000 program/erase cycles might be expected, with QLC memory cells (e.g., four digits per memory cell), a useful life might be as low as 2,000 program/erase cycles. The ranges PE1-PE0, PE2-PE1, PE3-PE2, PE4-PE3, and PE5-PE4 might each be equal. Alternatively, the ranges PE1-PE0, PE2-PE1, PE3-PE2, PE4-PE3, and PE5-PE4 might be independent of one another. For example, they might be selected to facilitate equal numbers of groupings of memory cells assigned to each corresponding indication of determined endurance.

TABLE 1
Indication of Determined Endurance as a Function
of Number of Program/Erase Cycles at End-of Life

| Indication of | Number of Program/Erase Cycles | |
|---|---|---|
| Determined | Greater Than or | |
| Endurance | Equal To | Less Than |
| Failed | | PE0 |
| 0 | PE0 | PE1 |
| 1 | PE1 | PE2 |
| 2 | PE2 | PE3 |
| 3 | PE3 | PE4 |
| 4 | PE4 | PE5 |
| 5 | PE5 | |

Alternatively, a clustering algorithm might be used to assign different groupings of memory cells to the different indications of determined endurance. Clustering algorithms might include K-mean, hierarchical clustering, spectral clustering, fuzzy clustering, affinity propagation, DBSCAN (density-based spatial clustering of applications with noise), agglomerative clustering, or any other suitable methods of grouping results into separate classes. Indications of determined endurance for a cluster might be assigned in response to a representative level of determined endurance for the cluster. For example, a mean, median or mode of some metric of each cluster might be used to rank their levels of endurance.

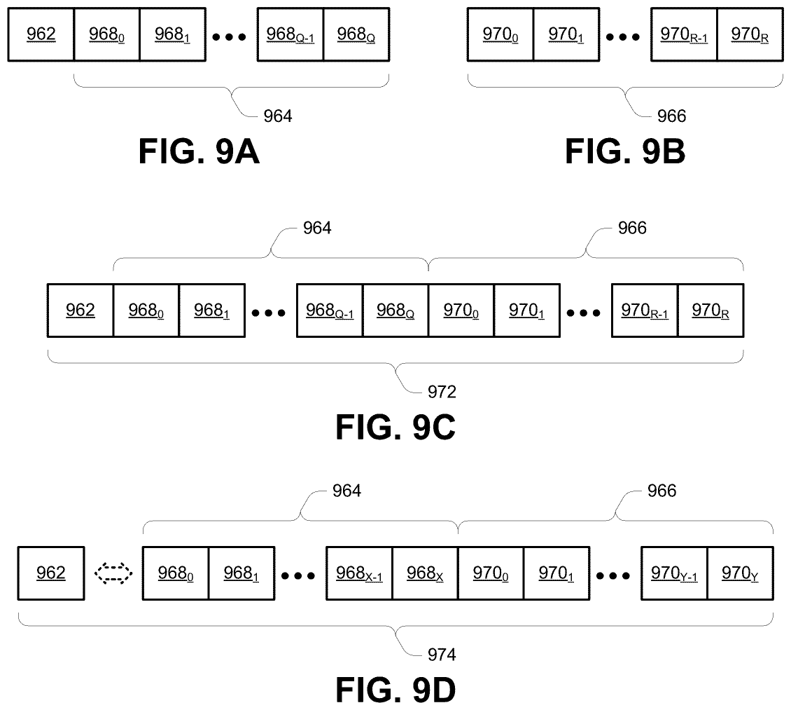

At 488, the labeled characterization data and the process data might be joined. FIG. 9A depicts a representation of one entry of a labeled characterization dataset corresponding to one grouping of memory cells having a label 962 (e.g., an indication of determined endurance) and having characterization data 964 including one or more characterization data elements 968 (e.g., 968₀-968_{Q}). FIG. 9B depicts a representation of one entry of a process dataset corresponding to a same grouping of memory cells having process data 966 including one or more process data elements 970 (e.g., 970₀-970_{R}). As some data elements 970 of the process data 966 might correspond to a die 512, or even a wafer 510, as a whole, some data elements 970 might be repeated for multiple groupings of memory cells (e.g., multiple entries of the process dataset). For some embodiments, an entry of the process dataset might be the same for each grouping of memory cells of a die 512, and might even be the same for each die 512, and thus each grouping of memory cells, of a wafer 510.

FIG. 9C depicts a representation of one entry of a training dataset 972 for one grouping of memory cells including its corresponding label 962, its corresponding characterization data 964 including its one or more characterization data elements 968 (e.g., 968₀-968_{Q}), and its corresponding process data 966 including its one or more process data elements 970 (e.g., 970₀-970_{R}). The training dataset 972 might represent training data for the predictive model. Although only one entry of the training dataset 972 is depicted in FIG. 9C, it might generally include many more entries, e.g., many thousands of entries.

FIG. 9D depicts a representation of one entry of a validation dataset 974 for a different grouping of memory cells including an entry of characterization data 964 including one or more characterization data elements 968 (e.g., 968₀-968_{X}) and process data 966 including one or more process data elements 970 (e.g., 970₀-970_{Y}) that are associated with a label 962, e.g., an indication of determined endurance. The validation dataset 974 might represent an entry of data for testing and validating the predictive model, and might be generated, and labeled, in a same manner as described with reference to the training dataset 972. In general, the characterization data 964 and process data 966 of an entry of the validation dataset 974 might be provided to the predictive model, and the result might be compared to the label 962 associated with that entry of the validation dataset 974.

Note that the one or more characterization data elements 968 (e.g., 968₀-968_{Q}) of the training dataset 972 might not necessarily correspond in a one-to-one manner with the one or more characterization data elements 968 (e.g., 968₀-968_{X}) of the validation dataset 974, and the one or more process data elements 970 (e.g., 970₀-970_{R}) of the training dataset 972 might not necessarily correspond in a one-to-one manner with the one or more process data elements 968 (e.g., 970₀-970_{Y}) of the validation dataset 974. For example, as the predictive model is validated and improved, a validation dataset 974 used in predicting an expected endurance of a grouping of memory cells might differ with regard to a number and/or type of data elements from one or more entries of the training dataset 972 used during initial training. In addition, in generating the training dataset 972, groupings of memory cells might be tested until an end-of-life condition is met, e.g., either for individual groupings of memory cells or for a die 512 containing those groupings of memory cells. While this permits determining an actual endurance of a grouping of memory cells, it generally destroys its ability to be of use to an end user. In contrast, for dies 512 being tested prior to sale, an abbreviated testing scheme might be used, thus generating an abbreviated dataset. For example, the characterization dataset 964 of the validation dataset 974 might contain less performance testing data, e.g., containing testing data for fewer program/erase cycles.

Although only one entry of the validation dataset 974 is depicted in FIG. 9D, it might generally include many more entries, e.g., many thousands of entries. However, the validation dataset 974 might include fewer entries than the training dataset 972 used for training the predictive model. For example, the validation dataset 974 might contain a fraction (e.g., one quarter) of the number of entries of the training dataset 972 used for initial training.

At 490, exploratory data analysis might optionally be performed. Exploratory data analysis might include visualizations of the joined dataset, such as histograms, scatter plots, box and whisker plots, line plots, bar charts, etc., of respective data elements from the entries of the training dataset 972 for a number of groupings of memory cells. Visualizations might permit discovering patterns, spotting anomalies, testing hypotheses, and/or checking assumptions, and might guide further improvement of a resulting predictive model.

At 492, feature engineering might optionally be performed. Features can be thought of as inputs to a machine learning model. Much of the data generated during fabrication of the dies 512 may have little impact on the accuracy of a predictive model for the expected endurance of individual groupings of memory cells. Those with knowledge of the fabrication process and its effects on the performance characteristics of the resulting groupings of memory cells might be able to guide the removal of data elements from, and possibly to guide the addition of data elements to, the process data 966 to improve the efficiency and/or accuracy of the resulting predictive model. Similarly, those with knowledge of the performance testing of the dies 512 might be able to guide the removal of data elements from, and possibly to guide the addition of data elements to, the characterization data 964 to improve the efficiency and/or accuracy of the resulting predictive model.

At 494, hyperparameter tuning might optionally be performed. Hyperparameters are generally configuration variables of a machine learning model. For example, hyperparameters might include a number of nodes and/or layers of a neural network, learning rate, learning rate decay, momentum, a number of branches of a decision tree, a number of times the training data is provided to the machine learning model, etc.

In general, one or more machine learning techniques might be applied to the training dataset 972. For example, such machine learning techniques might include one or more regression models (e.g., a set of statistical processes for estimating the relationships among variables), classification models, and/or phenomena models. Additionally, the machine-learning techniques might include a quadratic regression analysis, a logistic regression analysis, a support vector machine, a Gaussian process regression, ensemble models, or any other regression analysis. Furthermore, in yet further embodiments, the machine-learning techniques might include decision tree learning, regression trees, boosted trees, gradient boosted tree, multilayer perceptron, one-vs-rest, Naïve Bayes, k-nearest neighbor, association rule learning, a neural network, deep learning, pattern recognition, or any other type of machine learning. In yet further embodiments, the machine-learning techniques might include a multivariate interpolation analysis.

Using machine learning techniques, the predictive model might learn to correlate process and characterization data with an expected endurance of an individual grouping of memory cells. For example, for a given set of input values (e.g., the process data generated during fabrication of dies 512 on a wafer 510, and performance testing [e.g., non-destructive performance testing] and location information gathered subsequent to fabrication), the predictive model might be expected to generate an indication of expected endurance that might approximate or equal an indication of determined endurance that might be generated as a result of destructive testing. The predictive model might thus be generated by iterating the machine learning training process for a relatively large number of groupings of memory cells.

At 496, the predictive model might be validated using a validation dataset 974. The predictive model might be configured to generate an indication of expected endurance for each entry of the validation dataset 974. For each entry of the validation dataset 974, the indication of expected endurance for that entry of the validation dataset 974 might be compared to the indication of determined endurance associated with that entry of the validation dataset 974 in order to assess the accuracy of the predictive model. If the accuracy is deemed to be sufficient, the predictive model could be utilized in subsequent embodiments as a multi-class classification model 498. If the accuracy is not deemed to be sufficient, or if the efficiency is deemed deficient, the process might return to 490 to seek to improve the accuracy and/or efficiency of the predictive model.

The accuracy of the predictive model might be determined using one or more statistical approaches. For example, the values of indication of expected endurance generated by the predictive model, and their corresponding values of indication of determined endurance from the label 962 of the validation dataset 974, might be subjected to a regression analysis, which is a statistical method used to make predictions based on observed values. The goodness-of-fit of a fitted regression line might be described by the coefficient R-squared (R²), which is a fraction defined by the dependent variable variance explained by the model divided by the total variance, which might range from 0 to 1, or 0% to 100%. Generally, higher values might indicate a higher degree of accuracy.

Alternatively, or in addition, the accuracy of the predictive model might be evaluated using a root-mean-square error (RMSE) analysis. RMSE generally measures an average difference between predicted and actual values. Generally, lower values might indicate a higher degree of accuracy, with values lower than 0.5 often being considered to indicate an accurate model. Other analyses might also be used as criteria for whether a predictive model is deemed to be sufficiently accurate.

Following generation of the predictive model, the model could be deployed. As previously noted, typical wear leveling schemes generally seek to increase the probability that a grouping of memory cells (e.g., super-block of memory cells, block of memory cells, sub-block of memory cells, page of memory cells, etc.) having a lower number of program/erase cycles would be selected for a programming operation over a grouping of memory cells having a higher number of program/erase cycles. The programming operation might be in response to a write command to store new data to the memory, or it might be in response to a housekeeping operation, e.g., moving valid data to a new storage location.

As noted, such wear leveling schemes will generally result in over-utilization of memory cells exhibiting a low level of endurance, and under-utilization of memory cells exhibiting a high level of endurance. To mitigate this issue, various embodiments seek to predict an expected endurance of a grouping of memory cells of a memory, using a predictive model, and to set a value of a count of its program/erase cycles in response to its expected endurance. This might essentially inflate an actual number of program/erase cycles performed on the grouping of memory cells in order to reduce its likelihood to be selected by the wear leveling scheme. In this manner, without altering the wear leveling scheme itself, groupings of memory cells expected to have a high level of endurance might be used more often than groupings of memory cells expected to have lower levels of endurance. As a result, the life of a memory containing the groupings of memory cells might be extended beyond its life using wear leveling alone.

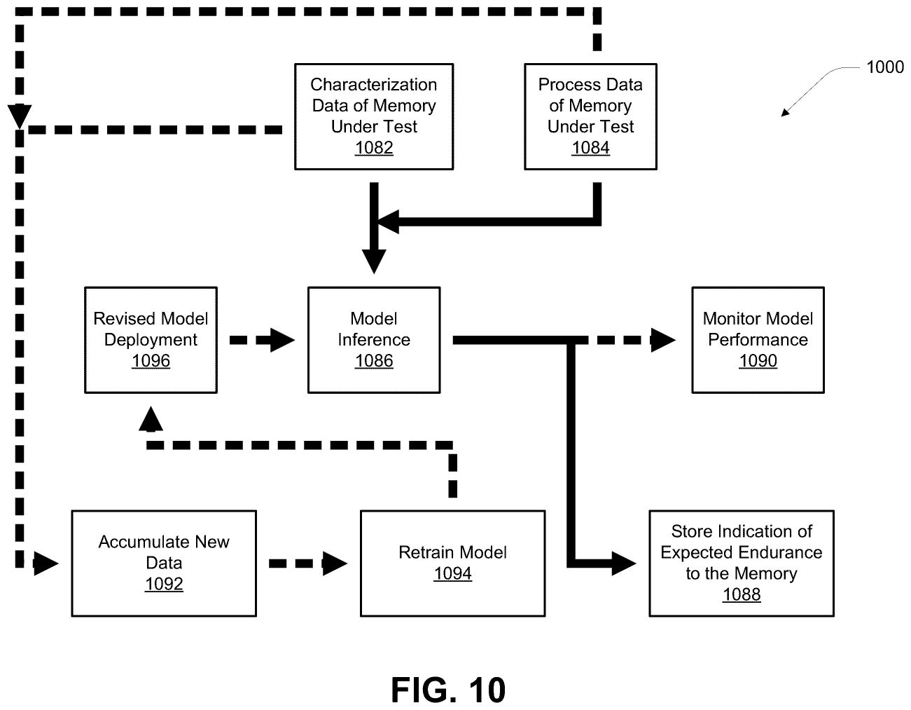

FIG. 10 depicts a flow diagram of an example process 1000 in accordance with an embodiment. The process 1000 might describe a process of training and tuning a predictive model (e.g., a machine learning model) to generate an indication of expected endurance of a grouping of memory cells.

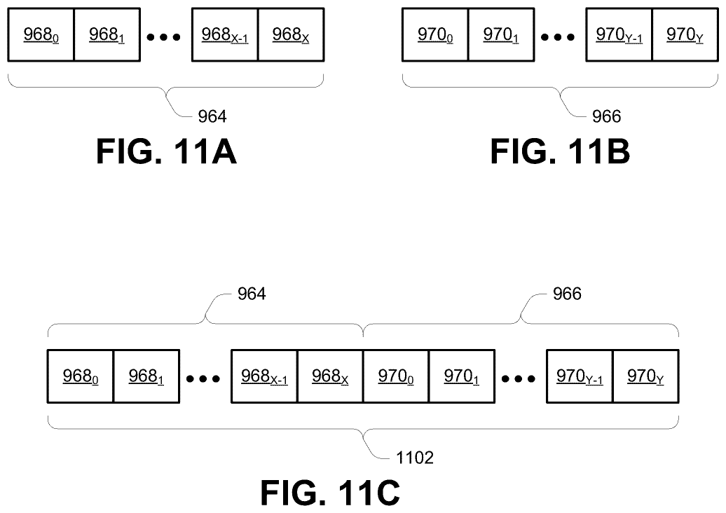

At 1082, characterization data corresponding to a grouping of memory cells of a memory under test might be generated. FIG. 11A depicts a representation of characterization data 964 corresponding to the grouping of memory cells of the memory under test, including one or more characterization data elements 968 (e.g., 968₀-968_{X}). The characterization data elements 968 might correspond to results of performance testing and location information corresponding to the grouping of memory cells, and might be generated and/or obtained as discussed with reference to FIGS. 4-6. The characterization data 964 corresponding to the grouping of memory cells of the memory under test might contain fewer characterization data elements 968 than the characterization data 964 of an entry of the training dataset 972. For example, in developing the training dataset 972 including assigning an indication of determined endurance (e.g., label 962), performance testing on a grouping of memory cells might extend to an end-of-life condition, e.g., either for the grouping of memory cells itself or the die 512 (memory 100) containing that grouping of memory cells. In contrast, the characterization data 964 corresponding to the grouping of memory cells of the memory under test at 1082 might be developed from an abbreviated testing scheme, e.g., to determine whether a die 512 (memory 100) meets some predefined performance criteria and/or quality standard.

At 1084, process data corresponding to the grouping of memory cells of the memory under test might be generated. FIG. 11B depicts a representation of process data 966 corresponding to the grouping of memory cells of the memory under test, including one or more process data elements 968 (e.g., 970₀-970_{Y}). The process data elements 970 might correspond to data generated and/or obtained during fabrication of a wafer 510 containing a die 512 (memory 100) corresponding to the grouping of memory cells as discussed with reference to FIGS. 4 and 7. The process data 966 corresponding to the grouping of memory cells of the memory under test might contain a same or different number of process data elements 970 than the process data 966 of an entry of the training dataset 972. Recall that the process data 966 of one grouping of memory cells of a memory might be the same for multiple groupings of memory cells of that memory, although the characterization data 964 for one grouping of memory cells of that memory might be independent of the characterization data 964 for each remaining grouping of memory cells of that memory.

At 1086, a model inference might be made for the grouping of memory cells in response to its corresponding characterization data 964 and process data 966. For example, the trained predictive model could be used to generate an indication of expected endurance for the grouping of memory cells using the characterization data 964 and process data 966 corresponding to the grouping of memory cells as inputs. Note that the characterization data 964 and process data 966 corresponding to the grouping of memory cells could be provided to the predictive model individually, or they could be combined into a joined dataset prior to input to the predictive model. FIG. 11C depicts a representation of a joined dataset 1102 containing the characterization data 964 corresponding to the grouping of memory cells of the memory under test, and the process data 966 corresponding to the grouping of memory cells.

At 1088, the indication of expected endurance for the grouping of memory cells might be stored to the memory. Storing of the indication of expected endurance might be performed by the tester hardware 502 in communication with the die 512 (memory 100) containing the grouping of memory cells. Additional detail on the storing and use of the indication of expected endurance will be subsequently described.

At 1090, the performance of the predictive model might optionally be monitored. For example, after generating the indication of expected endurance at 1086, performance testing might be continued until an end-of-life condition is met in order to generate an indication of determined endurance. The indication of determined endurance could then be compared to the indication of expected endurance to generate data for determining an accuracy of the predictive model. The comparison data could then be used to guide a decision whether to revise/retrain the predictive model.

Regardless of whether a desire to revise or retrain the predictive model is identified in response to model performance monitoring, retraining might occasionally or periodically be performed in response to continuing data generation. For example, processes and/or raw material sources might change, which could alter the performance characteristics of the fabricated memories. As new data is generated from periodic full testing, such as described with reference to FIG. 4, this data could be accumulated at 1092. The predictive model could then be retrained, e.g., through the use of exploratory data analysis 490, feature engineering 492, hyperparameter tuning 494, and/or validation 496. The revised predictive model could then be deployed at 1096 for use in generating future model inferences at 1086.

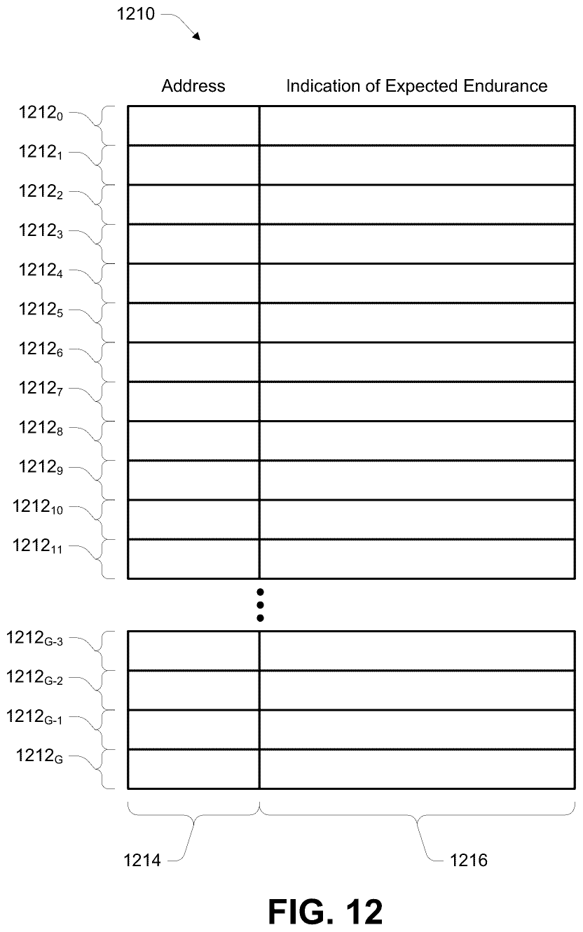

FIG. 12 depicts a look-up table 1210 containing G+1 entries 1212 (e.g., entries 1212₀-1212_{G}) corresponding to G+1 groupings of memory cells of a memory 100 (die 512). The look-up table 1210 might be stored to the register array 127. Each entry 1212 might contain an address 1214 identifying its corresponding grouping of memory cells, and an indication of expected endurance 1216 assigned to its corresponding grouping of memory cells. For example, the address 1214 corresponding to a grouping of memory cells might represent address information used to access each memory cell of that grouping of memory cells. Alternatively, the address 1214 corresponding to a grouping of memory cells might represent some other unique value identifying the memory cells of that grouping of memory cells.

The indication of expected endurance 1216 corresponding to a grouping of memory cells might represent a unique value corresponding to its expected endurance. For example, where the predictive model might assign one of eight indications of expected endurance, each indication might correspond to a respective value 000, 001, 010, 011, 100, 101, 110, and 111.

Alternatively, the indication of expected endurance 1216 corresponding to a grouping of memory cells might represent an initial value of a program/erase count for that grouping of memory cells to be used by the memory in wear leveling operations. In this regard, groupings of memory cells assigned to lower levels of expected endurance might have higher initial values of a program/erase count than groupings of memory cells assigned to higher levels of expected endurance in order to improve the likelihood that the wear leveling scheme used by the memory will select groupings of memory cells assigned to higher levels of expected endurance more often than groupings of memory cells assigned to lower levels of expected endurance. For example, if a highest level of expected endurance corresponds to 100,000 program/erase cycles before end-of-life, and a lower level of expected endurance corresponds to 80,000 program/erase cycles before end-of-life, a grouping of memory cells assigned to the highest level of expected endurance might have an indication of expected endurance of 0, while a grouping of memory cells assigned to the lower level of expected endurance might have an indication of expected endurance of 20,000 (e.g., 100,000-80,000).

The tester hardware 502, in communication with the memory 100 under test, might store the indications of expected endurance 1216, and might optionally store the respective addresses 1214, for each grouping of memory cells of a memory 100 under test to the look-up table 1210. Upon initialization of the memory 100 subsequent to testing, initial values of respective program/erase counts might be generated in response to the indications of expected endurance, and might be stored to the array of memory cells for use during wear leveling operations. Storing the initial values of respective program/erase counts might involve a direct transfer of the values of the indications of expected endurance 1216 where the indications of expected endurance 1216 represent an initial value of a program/erase count.

Alternatively, storing the initial values of respective program/erase counts might involve storing values corresponding to the indications of expected endurance, and storing initial values of respective program/erase counts in response to the indications. Returning to the example of eight indications of expected endurance, where 000<001<010<011<100<101<110<111 with regard to levels of expected endurance, a controller (e.g., control logic 116) might be configured (e.g., in response to machine-readable instructions stored to the instruction registers 128) to store a first count C1 in response to an indication of expected endurance of 000, a second count C2 in response to an indication of expected endurance of 001, and continuing in like fashion to an eighth count C8 in response to an indication of expected endurance of 111, where C1>C2>C3>C4>C5>C6>C7>C8. Note that the program/erase count corresponding to a highest level of expected endurance might have a value of zero or a non-zero value.

For embodiments storing an initial program/erase count as an indication of expected endurance 1216 in look-up table 1210, such embodiments might further maintain ongoing program/erase counts within the look-up table 1210. For example, in response to a grouping of memory cells corresponding to an entry 1212 of the look-up table 1210 undergoing a program/erase cycle, its program/erase count (e.g., stored to the indication of expected endurance 1216) might be incremented by 1.

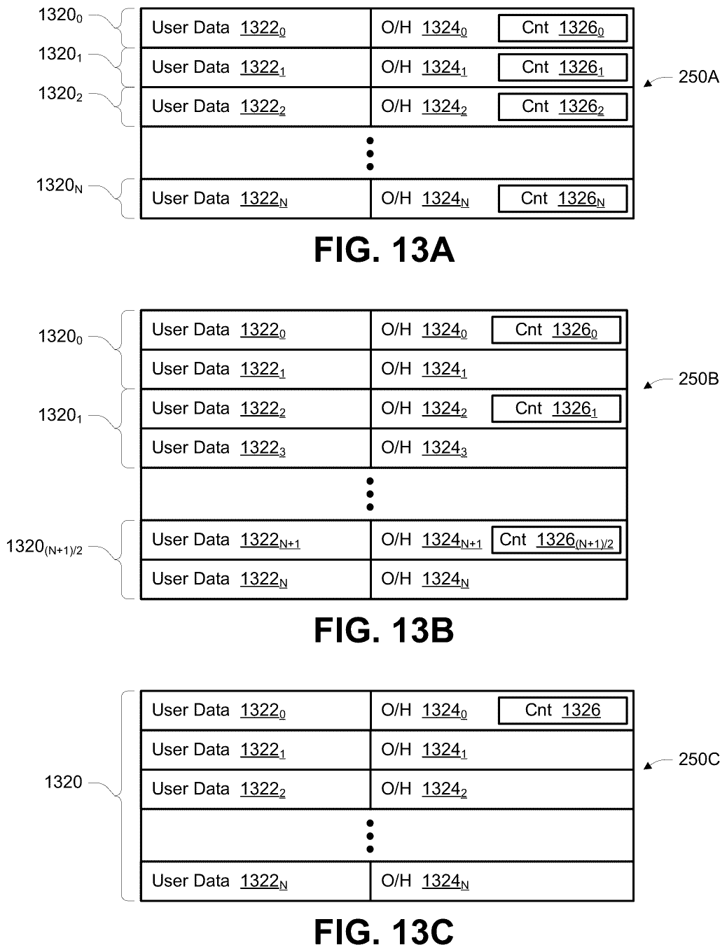

Alternatively, the program/erase counts might be stored in the array of memory cells 104 in association with their respective groupings of memory cells. FIGS. 13A-13C depict various examples of how counts used by a wear leveling scheme, e.g., program/erase counts, might be stored in relation to blocks of memory cells in accordance with some embodiments.

In FIG. 13A, a block of memory cells 250A might have N+1 groupings of memory cells 1320 (e.g., groupings of memory cells 1320₀-1320_{N}). Each grouping of memory cells 1320 might correspond to a page of memory cells (e.g., physical page of memory cells) having a corresponding user data portion 1322 (e.g., user data portions 1322₀-1322_{N}) and a corresponding overhead data (O/H) portion 1324 (e.g., O/H portions 1324₀-1324_{N}). A user data portion 1322 might be configured to store user data, e.g., data that might accessible to a user of the memory under normal operating conditions such as in response to a read command, while an O/H portion 1324 might be configured to store overhead data, e.g., data that might be inaccessible to a user of the memory under normal operation conditions, and might be used internally by the memory or might be accessible to an external device (e.g., a memory controller) for use in controlling operation of the memory. Examples might include block management data, status information or an error correction code (ECC). As one particular example, each O/H portion 1324 of the block of memory cells 250A might store a program/erase count 1326 (e.g., program/erase counts 1326₀-1326_{N}) for its corresponding grouping of memory cells 1320. Alternatively, the program/erase count 1326 corresponding to a grouping of memory cells 1320 might be stored to an O/H portion 1324 different from its corresponding O/H portion 1324. For example, each program/erase count 1326₀-1326_{N} of the block of memory cells 250A might be stored to the O/H portion 1324₀ or some other O/H portion 1324 or combination of O/H portions 1324 of the block of memory cells 250A or even a different block of memory cells 250.

In FIG. 13B, a block of memory cells 250B might have (N+1)/2 groupings of memory cells 1320 (e.g., groupings of memory cells 1320₀-1320_{(N+1)/2}). Each grouping of memory cells 1320 might correspond to a subset of pages of memory cells (e.g., physical page of memory cells) of the block of memory cells 250B. In the example of FIG. 13B, each grouping of memory cells 1320 corresponds to a subset of two pages of memory cells (e.g., two user data portions 1322 and their corresponding O/H portions 1324). As one particular example, one O/H portion 1324 of each grouping of memory cells 1320 of the block of memory cells 250B might store a program/erase count 1326 (e.g., program/erase counts 1326₀-1326_{(N+1)/2}) for its corresponding grouping of memory cells 1320. Alternatively, the program/erase count 1326 corresponding to a grouping of memory cells 1320 might be stored to an O/H portion 1324 different than one of its corresponding O/H portions 1324. For example, each program/erase count 1326₀-1326_{(N+1)/2} of the block of memory cells 250B might be stored to the O/H portion 1324₀ or some other O/H portion 1324 or combination of O/H portions 1324 of the block of memory cells 250B or even a different block of memory cells 250.

In FIG. 13C, a block of memory cells 250C might have one grouping of memory cells 1320. The grouping of memory cells 1320 might correspond to all pages of memory cells (e.g., physical page of memory cells) of the block of memory cells 250C, e.g., might correspond to the block of memory cells 250C. An O/H portion 1324 (e.g., O/H portion 1324₀ in this example) of the grouping of memory cells 1320 of the block of memory cells 250C might store a program/erase count 1326 for the corresponding grouping of memory cells 1320. Alternatively, the program/erase count 1326 corresponding to the grouping of memory cells 1320 might be stored to a different O/H portion 1324 of the block of memory cells 250C, or to an O/H portion 1324 of a different block of memory cells 250.

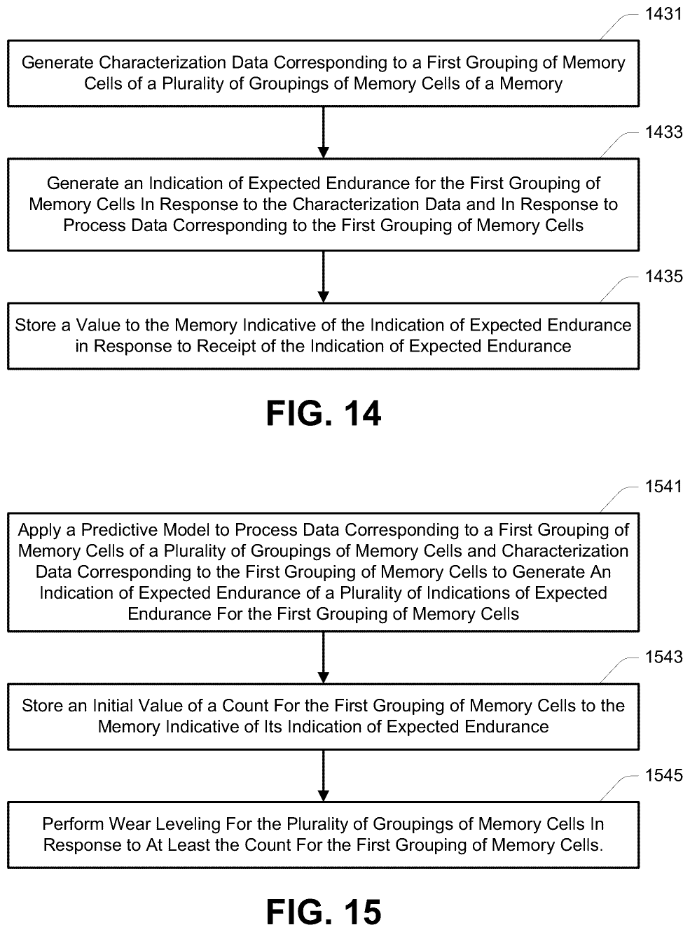

FIG. 14 depicts a flowchart of a method of operating a system containing a tester hardware and a predictive model according to an embodiment. The method might be in the form of computer-readable instructions, e.g., stored to one or more storage components such as the storage components 366 and/or 506. Such computer-readable instructions might be executed by one or more controllers, e.g., the controllers 364 and/or 504.

At 1431, characterization data corresponding to a first grouping of memory cells of a plurality of groupings of memory cells of a memory might be generated. For example, a die containing a memory might be connected to a set of leads of tester hardware. A controller of the tester hardware might be configured to cause the tester hardware to generate the characterization data. The characterization data might include at least location information corresponding to the first grouping of memory cells. The characterization data might further include performance testing data corresponding to the first grouping of memory cells.

The location information might include at least identification of the die connected to the set of leads relative to a wafer upon which the die connected to the set of leads was fabricated. Identification of a die relative to a wafer upon which the die was fabricated might include an assigned die identification number, Cartesian coordinates of the wafer for the die, polar coordinates of the wafer for the die, and/or row and column of the wafer for the die. The location information might further include identification of the grouping of memory cells within an array of memory cells of the memory. For example, the location information might further include an address used by the memory of the die to access a grouping of memory cells. An address used by the memory of the die to access a grouping of memory cells might include a single address or a range of addresses.

Each grouping of memory cells might be a page of memory cells of a block of memory cells, a subset of pages of memory cells of a block of memory cells, a block of memory cells, or a super block of memory cells.

At 1433, an indication of expected endurance for the first grouping of memory cells might be generated in response to the characterization data for the first grouping of memory cells and in response to process data corresponding to the first grouping of memory cells. For example, a predictive model might be configured to generate the indication of expected endurance in response to the input data.

The process data might include data generated during fabrication of the die connected to the set of leads. As discussed, some data elements of process data might be the same for each grouping of memory cells of a die, and might further be the same for each die fabricated on a same wafer. Other data elements of process data might be the same for only a subset of groupings of memory cells, or for only a subset of dies fabricated on a same wafer.

At 1435, in response to receipt of the indication of expected endurance for the first grouping of memory cells, a value might be stored to the memory of the die connected to the set of leads that is indicative of the indication of expected endurance for the first grouping of memory cells. For example, the tester hardware might receive the indication of expected endurance from the predictive model, and the controller of the tester hardware might store the value indicative of the indication of expected endurance to the memory. The value stored to the memory indicative of the indication of expected endurance might be a value of the indication of expected endurance. Alternatively, the value stored to the memory indicative of the indication of expected endurance might include an initial value of a count to be used by a wear leveling scheme of the memory.

The method of FIG. 14 might be repeated for each grouping of memory cells of the plurality of groupings of memory cells, generating respective indications of expected endurance in response to respective characterization data and process data, and storing respective values to the memory indicative of their respective indications of expected endurance in response to receiving the respective indications of expected endurance. Alternatively, the method of FIG. 14 might be repeated for a subset of groupings of memory cells (e.g., less than all groupings of memory cells) of the plurality of groupings of memory cells. For such embodiments, a value indicative of the respective indication of expected endurance for one grouping of memory cells might be stored to the memory for one or more other groupings of memory cells of the plurality of groupings of memory cells. The method of FIG. 14, e.g., for all or less than all groupings of memory cells of a memory, might further be repeated for each die of a wafer, with each die containing a respective memory.

The decision to apply a value indicative of the respective indication of expected endurance for one grouping of memory cells to another grouping of memory cells might be in response to an expected similarity in the operation of the two groupings of memory cells. This might be indicated by proximity. For example, neighboring groupings of memory cells might be expected to have similar endurance levels, such that a determination for one grouping of memory cells might be deemed to be a determination for one or more adjacent groupings of memory cells. This might include immediately adjacent groupings of memory cells, but might further extend to groupings of memory cells of lower degrees of adjacency, e.g., separated by one or more groupings of memory cells.

FIG. 15 depicts a flowchart of a method of performing wear leveling according to an embodiment. The method might be performed on a system containing a tester hardware, a predictive model, and a memory. The method might be in the form of computer-readable instructions, e.g., stored to one or more storage components such as the storage components 366 and/or 506, or instruction registers 128. Such computer-readable instructions might be executed by one or more controllers, e.g., the controllers 364 and/or 504, and control logic 116.

At 1541, a predictive model might be applied to process data corresponding to a first grouping of memory cells of a plurality of groupings of memory cells and characterization data corresponding to the first grouping of memory cells to generate an indication of expected endurance for the first grouping of memory cells. The indication of expected endurance might be one of a plurality of possible indications of expected endurance for the first grouping of memory cells.

The process data corresponding to the first grouping of memory cells might be generated in response to fabrication of a die containing a memory comprising the plurality of groupings of memory cells. The process data for the first grouping of memory cells might include a plurality of data elements. The characterization data corresponding to the first grouping of memory cells might be generated in response to testing of the die. The characterization data might include a plurality of data elements, including performance testing and location information for the first grouping of memory cells.

Some data elements of the process data corresponding to the first grouping of memory cells might be the same as corresponding data elements for process data corresponding to one or more other groupings of memory cells, up to all remaining groupings of memory cells, of the plurality of groupings of memory cells. Similarly, some data elements of the process data corresponding to the first grouping of memory cells might be different than corresponding data elements for process data corresponding to one or more other groupings of memory cells, up to all remaining groupings of memory cells, of the plurality of groupings of memory cells.

At 1543, an initial value of a count for the first grouping of memory cells might be stored to the memory indicative of its indication of expected endurance. The count might correspond to a value used by a wear leveling scheme to determine which groupings of memory cells to select from a programming operation. Typically, this might be a program/erase count, but it could also correspond to a program count, an erase count, or any other count that might indicate wear on the grouping of memory cells. Storing an initial value of a count might involve storing a first value indicative of the indication of expected endurance, and converting the first value to the initial value of the count.

At 1545, wear leveling for the plurality of groupings of memory cells might be performed in response to at least the count for the first grouping of memory cells. Note that as wear leveling is performed, the count value of the first grouping of memory cells might be incremented to indicate increased wear, e.g., in response to a program/erase cycle for embodiments utilizing a program/erase count in the wear leveling scheme.

The method of FIG. 15 might be repeated for each grouping of memory cells of the plurality of groupings of memory cells, applying the predictive model to respective process data and characterization data, storing respective initial values of counts to the memory, and performing wear leveling for the plurality of groupings of memory cells in response to each of the counts.

Alternatively, the method of FIG. 15 might be repeated for a subset of groupings of memory cells (e.g., less than all groupings of memory cells) of the plurality of groupings of memory cells. For such embodiments, an initial value of a count for one grouping of memory cells might be stored to the memory for one or more other groupings of memory cells of the plurality of groupings of memory cells. The decision to apply an initial value for one grouping of memory cells to another grouping of memory cells might be in response to an expected similarity in the operation of the two groupings of memory cells. This might be indicated by proximity as previously noted.

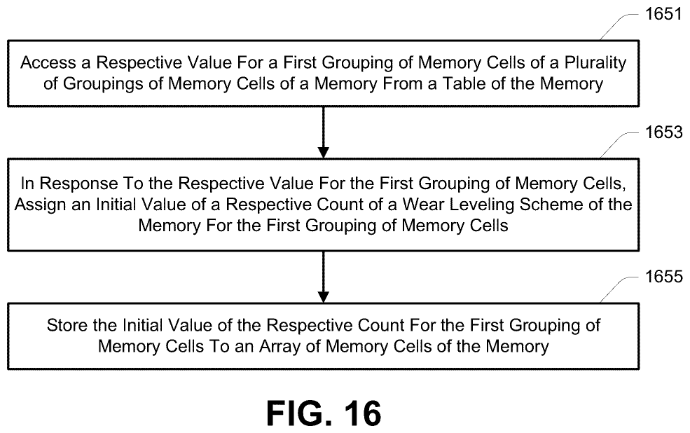

FIG. 16 depicts a flowchart of a method of operating a memory according to an embodiment. The method might be in the form of computer-readable instructions, e.g., stored to one or more storage components such as the instruction registers 128. Such computer-readable instructions might be executed by a controller, e.g., the control logic 116. The method of FIG. 16 might be performed during an initialization of the memory, e.g., a process that might be performed once following fabrication of the memory to prepare the memory for use by an end user.

At 1651, a respective value for a first grouping of memory cells of a plurality of groupings of memory cells of a memory might be accessed from a look-up table of the memory. The first grouping of memory cells might correspond to an entry 1212 of the look-up table 1210 of FIG. 12 identified by one of the addresses (which might include a range of addresses) 1214 and having a respective indication of expected endurance 1216. As such, a controller of the memory might cause the memory to read the value of its respective indication of expected endurance 1216 from its corresponding entry 1212.

At 1653, an initial value of a respective count of a wear leveling scheme of the memory for the first grouping of memory cells might be assigned in response to the respective value for the first grouping of memory cells. The initial value of the respective count might be equal to the respective value accessed from the look-up table. Alternatively, the controller of the memory might cause the memory to convert the respective value for the first grouping of memory cells to the initial value of its respective count. This might be performed in response to another look-up table. Table 2 is an example of a look-up table for use in such a conversion, and might be stored in a register array (e.g., register array 128) of the memory. Table 2 depicts one possible relationship between values accessed from the look-up table 1210 of FIG. 12, and initial values of counts to be stored to the array of memory cells. In Table 2, Value₀ indicates a lower indication of expected endurance than Value₁, Value₁ indicates a lower indication of expected endurance than Value₂, Value₂ indicates a lower indication of expected endurance than Value₃, and so on. As such, the initial values of the counts have the following relationship:

$${Count}_{0} > {Count}_{1} > {Count}_{2} > {Count}_{3} > {Count}_{4} > {Count}_{5} > {Count}_{6} > {Count}_{7} .$$

TABLE 2
Value of Indication of Expected
Endurance vs Initial Value of
Count

| Value of Indication of | Initial Value |
|---|---|
| Expected Endurance | of Count |
| Value₀ | Count₀ |
| Value₁ | Count₁ |
| Value₂ | Count₂ |
| Value₃ | Count₃ |
| Value₄ | Count₄ |
| Value₅ | Count₅ |
| Value₆ | Count₆ |
| Value₇ | Count₇ |

Alternatively to using a look-up table to convert the respective value for the first grouping of memory cells to the initial value of its respective count, a function could be used to convert from one value to another satisfying the relationship that lower levels of expected endurance should have higher initial values of their counts to be used by the wear leveling scheme of the memory.

The count might correspond to a value used by a wear leveling scheme to determine which groupings of memory cells to select for a programming operation. Typically, this might be a program/erase count, but it could also correspond to a program count, an erase count, or any other count that might indicate wear on the grouping of memory cells.

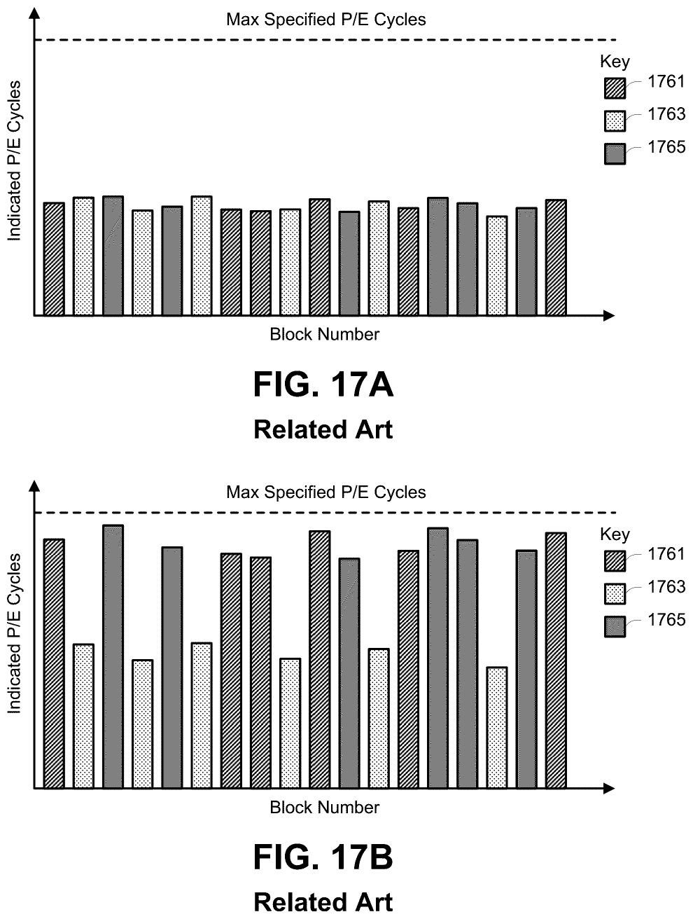

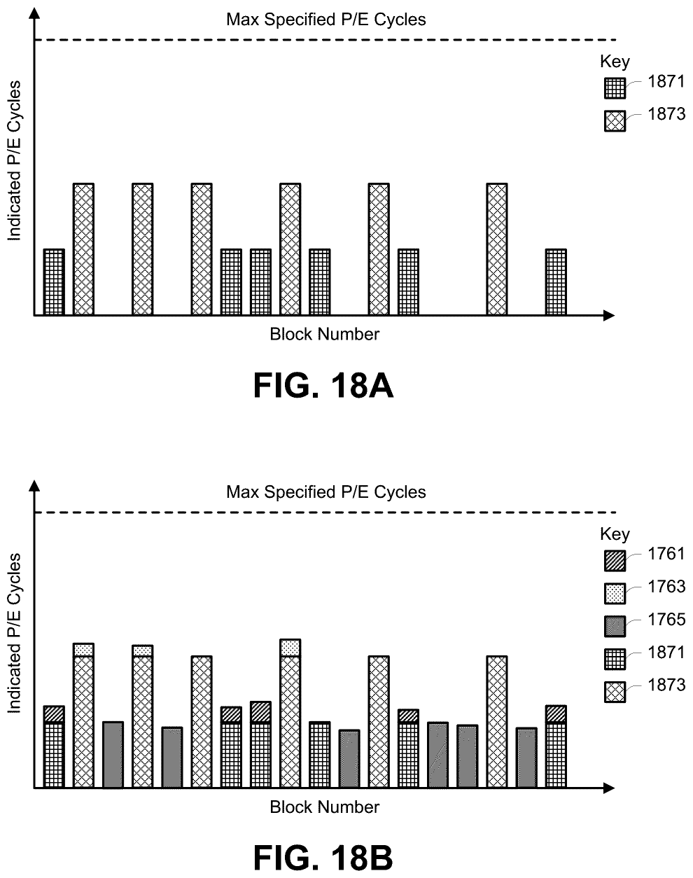

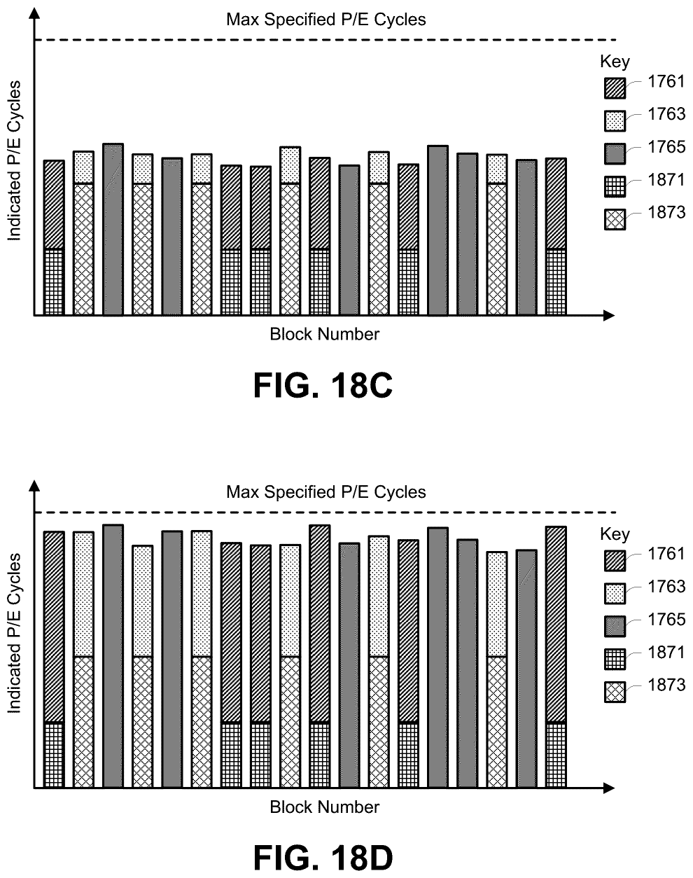

Although advantages of various embodiments have been discussed in the text, the following figures provide a depiction of some advantages. FIGS. 17A-17B depict stages of traditional wear leveling in a memory, while FIGS. 18A-18D depict stages of wear leveling in a memory in accordance with embodiments. It is noted that the wear leveling scheme used in the example of FIGS. 17A-17B might be a same wear leveling scheme as used in the example of FIGS. 18A-18D.

It is common to specify a maximum number of P/E cycles that a memory might reliably experience for its rated capacity. This value might be expressed as a number of P/E cycles per block of memory cells, for example. As previously noted, different groupings of memory cells, e.g., blocks of memory cells, of a memory might be expected to have differing levels of endurance. As such, some blocks of memory cells might be expected to fail before reaching the specified maximum, some blocks of memory cells might be expected to fail at or near the specified maximum, and some blocks of memory cells might be expected to have a useful life beyond the specified maximum. The following examples will look at a simplified hypothetical example having only three classes of blocks of memory cells, e.g., a first subset of blocks of memory cells 1761 having an expected endurance at or near the maximum specified P/E cycles, a second subset of blocks of memory cells 1763 having an expected endurance around 50% of the maximum specified P/E cycles, and a third subset of blocks of memory cells 1765 having an expected endurance around 150% of the maximum specified P/E cycles. While actual memories might be expected to have a more sophisticated distribution of endurance levels, this simplified hypothetical can be used to demonstrate differences between the prior art and various embodiments described herein.

FIG. 17A might depict a distribution of indicated P/E cycles from the different blocks of memory cells of a memory early in the life of the memory. In FIG. 17A, due to the operation of traditional wear leveling, the indicated, and actual, P/E cycles for the first subset of blocks of memory cells 1761, for the second subset of blocks of memory cells 1763, and for the third subset of blocks of memory cells 1765 might all be similar. FIG. 17B might depict a distribution of indicated P/E cycles from the different blocks of memory cells of the memory nearer the end of the life of the memory. In FIG. 17B, as blocks of memory cells of the second subset of blocks of memory cells 1763 reach the end of their life, these failed blocks of memory cells are now longer available to the wear leveling scheme, such that only blocks of memory cells of the first subset of blocks of memory cells 1761 and of the third subset of blocks of memory cells 1765 are available for use. As a result, the indicated P/E cycles of the first subset of blocks of memory cells 1761 and the third subset of blocks of memory cells 1765 will continue to increase while the indicated P/E cycles of the second subset of blocks of memory cells 1763 will cease to increase. In order to satisfy the maximum specified P/E cycles, and to maintain its rated capacity, the memory of the hypothetical would require sufficient redundant blocks of memory cells of the first and third subsets of blocks of memory cells to offset the deficiency caused by the early failure of the blocks of memory cells of the second subset of blocks of memory cells.

FIG. 18A might depict a distribution of indicated P/E cycles from the different blocks of memory cells of a memory upon initialization of the memory. In FIG. 18A, blocks of memory cells corresponding to the first subset of blocks of memory cells 1761 might each be assigned an initial count 1871, while blocks of memory cells corresponding to the second subset of blocks of memory cells 1763 might each be assigned an initial count 1873. The initial count 1873 for the indicated P/E cycles for the second subset of blocks of memory cells 1763 might be greater than the initial count 1871 for the indicated P/E cycles for the first subset of blocks of memory cells 1761 due to the lower expected endurance of the blocks of memory cells of the second subset of blocks of memory cells 1763. The blocks of memory cells corresponding to the third subset of blocks of memory cells 1765 might not have a corresponding initial count, e.g., the initial count might be zero. For various embodiments, the indicated P/E cycles for a block of memory cells or other grouping of memory cells, might be different from its actual P/E cycles.

FIG. 18B might depict a distribution of indicated P/E cycles from the different blocks of memory cells of the memory early in the life of the memory. Due to the lower indicated P/E cycles for the third subset of blocks of memory cells 1765, wear leveling schemes might be expected to primarily use blocks of memory cells of the third subset of blocks of memory cells 1765. In contrast, blocks of memory cells of the first subset of blocks of memory cells 1761 and of the second subset of blocks of memory cells 1763 might see little or no use depending upon the number of blocks of memory cells actively storing data. Use of the blocks of memory cells indicating higher P/E cycles is possible because various embodiments might not actively restrict a wear leveling scheme from using these blocks of memory cells. However, because the indicated P/E cycles of the blocks of memory cells of the first subset of blocks of memory cells 1761 and of the second subset of blocks of memory cells 1763 are higher than their actual P/E cycles, a wear leveling scheme would be less likely to select them when seeking out a free block of memory cells.

FIG. 18C might depict a distribution of indicated P/E cycles from the different blocks of memory cells of the memory later in the life of the memory than depicted in FIG. 18B. As the wear leveling scheme continues to favor use of blocks of memory cells of the third subset of blocks of memory cells 1765, their indicated P/E cycles will become similar to the indicated P/E cycles of blocks of memory cells of the first subset of blocks of memory cells 1761. As a result, indicated P/E cycles of the blocks of memory cells of the first subset of blocks of memory cells 1761 and of the third subset of blocks of memory cells 1765 will become similar to the indicated P/E cycles of blocks of memory cells of the second subset of blocks of memory cells 1763.

FIG. 18D might depict a distribution of indicated P/E cycles from the different blocks of memory cells of the memory later in the life of the memory than depicted in FIG. 18C. With the indicated P/E cycles of the blocks of memory cells of the first subset of blocks of memory cells 1761, of the second subset of blocks of memory cells 1763, and of the third subset of blocks of memory cells 1765 being similar in FIG. 18C, the wear leveling scheme might tend to spread the use evenly among all of the blocks of memory cells of the memory such that the indicated P/E cycles of the blocks of memory cells of the first subset of blocks of memory cells 1761, of the second subset of blocks of memory cells 1763, and of the third subset of blocks of memory cells 1765 might remain similar for the remaining life of the memory.

As can be seen in FIG. 18D, although the blocks of memory cells of the first subset of blocks of memory cells 1761, of the second subset of blocks of memory cells 1763, and of the third subset of blocks of memory cells 1765 might present similar indicated P/E cycles to the wear leveling scheme at this stage in the life of the memory, their actual usage might vary considerably due to the initial counts 1871 and 1873 used for the blocks of memory cells of the first subset of blocks of memory cells 1761, and of the second subset of blocks of memory cells 1763, respectively. This ability to cause a wear leveling scheme to select higher-endurance groupings of memory cells more frequently than lower-endurance groupings of memory cells might maintain the rated capacity of a memory for a longer period of use, and might further facilitate a reduction in the number of redundant groupings of memory cells needed to satisfy a maximum number of P/E cycles that a memory might reliably experience for its rated capacity.

### CONCLUSION

Although specific embodiments have been illustrated and described herein, it will be appreciated by those of ordinary skill in the art that any arrangement that is calculated to achieve the same purpose might be substituted for the specific embodiments shown. Many adaptations of the embodiments will be apparent to those of ordinary skill in the art. Accordingly, this application is intended to cover any adaptations or variations of the embodiments.

What is claimed is:

1. A system, comprising:
a tester hardware comprising a controller, and a set of leads for connection to a die containing a memory comprising a plurality of groupings of memory cells;
a predictive model in communication with the tester hardware;
wherein the controller is configured to generate characterization data corresponding to a first grouping of memory cells of the plurality of groupings of memory cells, wherein the characterization data comprises at least location information corresponding to the first grouping of memory cells;
wherein the predictive model is configured to generate an indication of expected endurance for the first grouping of memory cells in response to the characterization data for the first grouping of memory cells and in response to process data corresponding to the first grouping of memory cells, wherein the process data comprises data generated during fabrication of the die; and
wherein the controller is further configured to store a value to the memory indicative of the indication of expected endurance for the first grouping of memory cells in response to receipt of the indication of expected endurance for the first grouping of memory cells from the predictive model.

2. The system of claim 1, wherein the predictive model is a machine learning model trained in response to a dataset comprising respective location information for each grouping of memory cells of a different plurality of groupings of memory cells, respective performance testing for each grouping of memory cells of the different plurality of groupings of memory cells, respective process data for each grouping of memory cells of the different plurality of groupings of memory cells, and a respective label corresponding to a determined endurance for each grouping of memory cells of the different plurality of groupings of memory cells.

3. The system of claim 2, wherein the respective performance testing for each grouping of memory cells of the different plurality of groupings of memory cells comprises performance testing extending to an end-of-life condition.

4. The system of claim 1, wherein the location information corresponding to the first grouping of memory cells comprises at least identification of the die relative to a wafer upon which the die was fabricated.

5. The system of claim 4, wherein the location information corresponding to the first grouping of memory cells further comprises an address used by the memory to access the first grouping of memory cells.

6. The system of claim 1, wherein the characterization data corresponding to the first grouping of memory cells further comprises performance testing data corresponding to the first grouping of memory cells.

7. The system of claim 1, wherein the first grouping of memory cells is selected from a group consisting of a page of memory cells of a block of memory cells, a subset of pages of memory cells of a block of memory cells, a block of memory cells, and a super block of memory cells.

8. The system of claim 1, wherein the value stored to the memory indicative of the indication of expected endurance for the first grouping of memory cells comprises an initial value of a count for use by a wear leveling scheme of the memory.

9. A method, comprising:
apply a predictive model to respective process data corresponding to a first grouping of memory cells of a plurality of groupings of memory cells and respective characterization data corresponding to the first grouping of memory cells to generate a respective indication of expected endurance of a plurality of indications of expected endurance for the first grouping of memory cells, wherein the respective process data corresponding to the first grouping of memory cells is generated in response to fabrication of a die containing a memory comprising the plurality of groupings of memory cells, and wherein the respective characterization data corresponding to the first grouping of memory cells is generated in response to testing of the die;
store an initial value of a respective count for the first grouping of memory cells to the memory indicative of its respective indication of expected endurance; and
perform wear leveling for the plurality of groupings of memory cells in response to at least the respective count for the first grouping of memory cells.

10. The method of claim 9, further comprising:
For G=2 to N step 1, wherein N is an integer value less than or equal to a number of groupings of memory cells of the plurality of groupings of memory cells:
apply the predictive model to respective process data corresponding to a G^{th} grouping of memory cells of the plurality of groupings of memory cells and respective characterization data corresponding to the G^{th} grouping of memory cells to generate a respective indication of expected endurance of the plurality of indications of expected endurance for the G^{th} grouping of memory cells, wherein the respective process data corresponding to the G^{th} grouping of memory cells is generated in response to the fabrication of the die, and wherein the respective characterization data corresponding to the G^{th} grouping of memory cells is generated in response to the testing of the die;
store an initial value of a respective count for the G^{th} grouping of memory cells to the memory indicative of its respective indication of expected endurance; and
perform wear leveling for the plurality of groupings of memory cells further in response to the respective count for the G^{th} grouping of memory cells.

11. The method of claim 10, wherein N is less than the number of groupings of memory cells of the plurality of groupings of memory cells, the method further comprising:
assign an initial value of a respective count for one grouping of memory cells of the plurality of groupings of memory cells to a different grouping of memory cells of the plurality of groupings of memory cells;
store the initial value of the respective count for the different grouping of memory cells to the memory; and
perform wear leveling for the plurality of groupings of memory cells further in response to the respective count for the different grouping of memory cells.

12. The method of claim 10, wherein the respective count for the each grouping of memory cells of the plurality of groupings of memory cells is a program/erase count of that grouping of memory cells.

13. The method of claim 10, wherein storing the initial value of the respective count for one grouping of memory cells to the memory indicative of its respective indication of expected endurance comprises storing a respective first value indicative of the respective indication of expected endurance for the one grouping of memory cells to the memory and converting its respective first value to the initial value of the respective count for the one grouping of memory cells.

14. The method of claim 10, wherein the respective characterization data for one grouping of memory cells of the plurality of groupings of memory cells comprises respective location information for that grouping of memory cells including identification of a location of the die within a wafer upon which it was fabricated, and identification of a location of the one grouping of memory cells within the memory.

15. A memory, comprising:
an array of memory cells comprising a plurality of groupings of memory cells;
a table comprising a respective address for each grouping of memory cells of the plurality of groupings of memory cells, and a respective value for each grouping of memory cells of the plurality of groupings of memory cells indicative of an expected endurance of its respective grouping of memory cells; and
a controller for access of the array of memory cells, wherein, during an initialization operation on the memory, the controller is configured to cause the memory to:
access the respective value for a first grouping of memory cells of the plurality of groupings of memory cells from the table;
in response to the respective value for the first grouping of memory cells, assign an initial value of a respective count of a wear leveling scheme of the memory for the first grouping of memory cells; and
store the initial value of the respective count for the first grouping of memory cells to the array of memory cells.

16. The memory of claim 15, wherein the controller being configured to cause the memory to assign the initial value of the respective count for the first grouping of memory cells in response to the respective value for the first grouping of memory cells comprises the controller being configured to cause the memory to assign the respective value for the first grouping of memory cells as the initial value of the respective count for the first grouping of memory cells.

17. The memory of claim 15, wherein the controller being configured to cause the memory to assign the initial value of the respective count for the first grouping of memory cells in response to the respective value for the first grouping of memory cells comprises the controller being configured to cause the memory to convert the respective value for the first grouping of memory cells to the initial value of the respective count for the first grouping of memory cells.

18. The memory of claim 17, wherein controller being configured to cause the memory to convert the respective value for the first grouping of memory cells to the initial value of the respective count for the first grouping of memory cells comprises the controller being configured to utilize a method selected from a group consisting of using a look-up table using a function.

19. The memory of claim 15, wherein the controller is further configured to cause the memory to:
access the respective value for each grouping of memory cells of the plurality of groupings of memory cells from the look-up table;
in response to the respective value for each grouping of memory cells, assign an initial value of a respective count of a wear leveling scheme of the memory for each grouping of memory cells; and
store the initial value of the respective count for each grouping of memory cells to the array of memory cells.

20. The memory of claim 19, wherein the initial value of the respective count for one grouping of memory cells of the plurality of groupings of memory cells is lower than the initial value of the respective count for each grouping of memory cells of the plurality of groupings of memory cells having a lower expected endurance than the one grouping of memory cells, and is higher than the initial value of the respective count for each grouping of memory cells of the plurality of groupings of memory cells having a higher expected endurance than the one grouping of memory cells.
